(19) United States
(12) Patent Application Publication
(10) Pub. No.: US 2026/0179660 A1
(43) Pub. Date: Jun. 25, 2026

(54) MEMORY DEVICE

(71) Applicant: Kioxia Corporation, Tokyo (JP)

(72) Inventor: Toshifumi HASHIMOTO, Fujisawa (JP)

(73) Assignee: Kioxia Corporation, Tokyo (JP)

(21) Appl. No.: 19/312,686

(22) Filed: Aug. 28, 2025

(30) Foreign Application Priority Data
Dec. 20, 2024 (JP) 2024-225205

(51) Int. Cl. G11C 5/06; G11C 16/04; G11C 16/26; G11C 16/30; G11C 16/32; H10B 41/10; H10B 41/27; H10B 41/35; H10B 41/41; H10B 43/10; H10B 43/27; H10B 43/35; H10B 43/40

(52) U.S. Cl. CPC G11C 5/063; G11C 16/0483; G11C 16/26; G11C 16/30; G11C 16/32; H10B 41/10; H10B 41/27; H10B 41/35; H10B 41/41; H10B 43/10; H10B 43/27; H10B 43/35; H10B 43/40

(57) ABSTRACT

A memory device includes a first string including first memory cells and a first transistor connected to the first memory cells; a second string including second memory cells and a second transistor connected to the second memory cells; word lines connected to respective gates of the first memory cells and respective gates of the second memory cells; a first wiring connected to a gate of the first transistor; a second wiring connected to a gate of the second transistor and disposed adjacent to the first wiring; and a control circuit configured to: apply a first voltage having a positive voltage value to each of the plurality of word lines; apply a second voltage having a positive voltage value to the first wiring; and apply a third voltage having a negative voltage value to the second wiring.

### CROSS-REFERENCE TO RELATED APPLICATION

This application is based upon and claims the benefit of priority from Japanese Patent Application No. 2024-225205, filed Dec. 20, 2024, the entire contents of which are incorporated herein by reference.

### FIELD

Embodiments described herein relate generally to a memory device.

### BACKGROUND

A NAND flash memory is known as a memory device capable of storing data in a non-volatile manner.

### DESCRIPTION OF THE DRAWINGS

FIG. 1 is a block diagram showing a configuration example of a memory device according to a first embodiment.

FIG. 2 is a circuit diagram showing a configuration example of a memory cell array of the memory device according to the first embodiment.

FIG. 3 is a diagram showing a relationship between data and a threshold voltage of a memory cell.

FIG. 4 is a schematic diagram showing a structure example of the memory device according to the first embodiment.

FIG. 5 is a plan view showing a structure example of the memory cell array of the memory device according to the first embodiment.

FIG. 6 is a cross-sectional view showing a structure example of the memory cell array of the memory device according to the first embodiment.

FIG. 7 is a cross-sectional view showing a structure example of a memory pillar.

FIG. 8 is a plan view showing a structure example of a select gate line of the memory device according to the first embodiment.

FIG. 9 is a plan view showing a structure example of the select gate line of the memory device according to the first embodiment.

FIG. 10 is a schematic diagram showing an outline of an operation of the memory device according to the first embodiment.

FIG. 11 is a schematic diagram showing an outline of the operation of the memory device according to the first embodiment.

FIG. 12 is a timing chart showing an example of the operation of the memory device according to the first embodiment.

FIG. 13 is a schematic diagram showing an outline of the operation of a memory device according to a second embodiment.

FIG. 14 is a schematic diagram showing an outline of the operation of the memory device according to the second embodiment.

FIG. 15 is a timing chart showing an example of the operation of the memory device according to the second embodiment.

FIG. 16 is a timing chart showing an example of the operation of a memory device according to a third embodiment.

FIG. 17 is a cross-sectional view showing a structure example of a memory cell array of a memory device according to a fourth embodiment.

FIG. 18 is a schematic diagram illustrating the configuration and operation of the memory device according to the fourth embodiment.

FIG. 19 is a schematic diagram showing an outline of an operation of a memory device according to a fifth embodiment.

FIG. 20 is a timing chart showing an example of the operation of the memory device according to the fifth embodiment.

FIG. 21 is a plan view showing a structure example of a memory cell array of a memory device according to a sixth embodiment.

FIG. 22 is a cross-sectional view showing a structure example of the memory cell array of the memory device according to the sixth embodiment.

FIG. 23 is a cross-sectional view showing a structure example of the memory cell array of the memory device according to the sixth embodiment.

FIG. 24 is a plan view showing a structure example of a select gate line of the memory device according to the sixth embodiment.

FIG. 25 is a plan view showing a structure example of a select gate line of the memory device according to the sixth embodiment.

FIG. 26 is a circuit diagram showing a configuration example of the memory cell array of the memory device according to the sixth embodiment.

FIG. 27 is a timing chart showing an example of the operation of the memory device according to the sixth embodiment.

FIG. 28 is a timing chart showing an example of the operation of the memory device according to the sixth embodiment.

FIG. 29 is a cross-sectional view showing a structure example of a memory cell array of a memory device according to a seventh embodiment.

FIG. 30 is a plan view showing a structure example of a select gate line of the memory device according to the seventh embodiment.

FIG. 31 is a circuit diagram showing a configuration example of the memory cell array of the memory device according to the seventh embodiment.

FIG. 32 is a plan view showing a structure example of a select gate line of a memory device according to an eighth embodiment.

FIG. 33 is a plan view showing a structure example of the select gate line of the memory device according to the eighth embodiment.

FIG. 34 is a cross-sectional view showing a structure example of a memory cell array of the memory device according to the eighth embodiment.

FIG. 35 is a cross-sectional view showing a structure example of the memory cell array of the memory device according to the eighth embodiment.

FIG. 36 is a circuit diagram showing a configuration example of the memory cell array of the memory device according to the eighth embodiment.

FIG. 37 is a cross-sectional view showing a structure example of a memory cell array of a memory device according to a ninth embodiment.

FIG. 38 is a cross-sectional view showing a structure example of the memory cell array of the memory device according to the ninth embodiment.

### DETAILED DESCRIPTION

Embodiments provide the improved operating characteristics of a memory device.

In general, according to one embodiment, a memory device includes: a first string including a plurality of first memory cells and a first transistor, the first transistor connected to one end of the plurality of first memory cells; a second string including a plurality of second memory cells and a second transistor, the second transistor connected to one end of the plurality of second memory cells; a plurality of word lines connected to respective gates of the plurality of first memory cells and respective gates of the plurality of second memory cells; a first wiring connected to a gate of the first transistor; a second wiring connected to a gate of the second transistor and disposed adjacent to the first wiring; and a control circuit operatively coupled to the first and second strings. When the first string is configured as an operation target during an operation, the control circuit is configured to: apply a first voltage having a positive voltage value to each of the plurality of word lines; apply a second voltage having a positive voltage value to the first wiring; and apply a third voltage having a negative voltage value to the second wiring.

### EMBODIMENTS

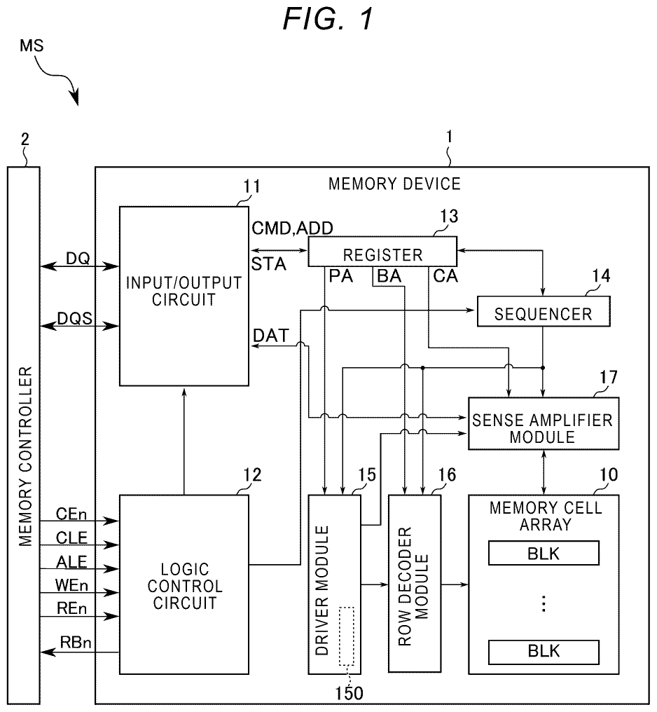

Memory devices and methods for controlling the memory devices according to embodiments will be described with reference to FIGS. 1 to 38. In the following description, elements having the same functions and configurations are given the same reference numerals. In addition, in each of the following embodiments, when components (for example, circuits, wiring, various voltages and signals, or the like) that are given reference symbols with distinguishing numbers/letters at the end do not need to be distinguished from each other, a description (reference symbol) with the final number/letter omitted is used.

### (1) First Embodiment

A memory device and a method for controlling the memory device according to a first embodiment will be described with reference to FIGS. 1 to 12.

### (a) Configuration Example

A configuration example of a memory device according to the present embodiment will be described with reference to FIGS. 1 to 9.

### (a-1) Circuit Configuration

The circuit configuration of the memory device of the present embodiment will be described with reference to FIGS. 1 to 3.

### (a-1-1) Internal Configuration of Memory Device

FIG. 1 is a block diagram showing a configuration example of a memory system including the memory device according to the present embodiment.

The memory system MS of FIG. 1 is a storage device configured to be connected to an external host device (not shown). The memory system MS is, for example, a memory card such as an SD™ card, a Universal Flash Storage (UFS), or a Solid State Drive (SSD).

The memory system MS includes a memory device 1 and a memory controller 2 of the present embodiment.

The memory controller 2 is configured with an integrated circuit such as a System on a Chip (SoC). The memory controller 2 controls the memory device 1 based on a request from the host device. Specifically, the memory controller 2 writes data requested to be written by the host device into the memory device 1. The memory controller 2 reads data requested to be read by the host device from the memory device 1 and transfers the data to the host device.

The memory device 1 is, for example, a semiconductor memory capable of storing data in a non-volatile manner. An example of the memory device 1 is a NAND flash memory.

The communication between the memory device 1 and the memory controller 2 complies with, for example, a Single Data Rate (SDR) interface, a Toggle Double Data Rate (DDR) interface, or an Open NAND Flash Interface (ONFI).

The memory device 1 includes, for example, a memory cell array 10, an input/output circuit 11, a logic control circuit 12, a register 13, a sequencer 14, a driver module 15, a row decoder module 16, and a sense amplifier module 17.

The memory cell array 10 is a collection of a plurality of memory cells and a plurality of select transistors. The memory cell array 10 includes a plurality of blocks BLK. The block BLK is a collection of a plurality of memory cells capable of storing data in a non-volatile manner. The block BLK is used, for example, as an erase unit when erasing data stored in the memory cells. A plurality of bit lines and a plurality of word lines are provided in the memory cell array 10. Each memory cell is associated with, for example, a combination of one bit line and one word line. The detailed configuration of the memory cell array 10 will be described later.

The input/output circuit 11 is an interface circuit that controls the transmission and reception of an input/output signal DQ between the memory device 1 and the memory controller 2. The input/output signal DQ includes, for example, data DAT, a command CMD, an address ADD, and status information STA. The input/output circuit 11 inputs and outputs data DAT between the sense amplifier module 17 and the memory controller 2. The input/output circuit 11 outputs the command CMD and the address ADD transferred from the memory controller 2 to the register 13. The input/output circuit 11 outputs the status information STA transferred from the register 13 to the memory controller 2. The input/output circuit 11 transmits and receives the input/output signal DQ in synchronization with the signal DQS.

The logic control circuit 12 receives various control signals input from the memory controller 2. The logic control circuit 12 controls each of the input/output circuit 11 and the sequencer 14 based on the control signal. For example, the logic control circuit 12 notifies the input/output circuit 11 that the input/output signal received by the input/output circuit 11 is a command CMD, an address ADD, or the like. The logic control circuit 12 instructs the input/output circuit 11 to input or output an input/output signal. The logic control circuit 12 controls the sequencer 14 to enable the memory device 1.

For example, the logic control circuit 12 receives, from the memory controller 2, a chip enable signal CEn, a command latch enable signal CLE, an address latch enable signal ALE, a write enable signal WEn, and a read enable signal REn. The chip enable signal CEn is a signal for enabling the chip of the memory device 1. The command latch enable signal CLE is a signal indicating that the signal DQ received by the memory device 1 is a command CMD. The address latch enable signal ALE is a signal indicating that the signal DQ received by the memory device 1 is an address ADD. The write enable signal WEn is a signal that instructs the memory device 1 to input the input/output signal DQ. The read enable signal REn is a signal that instructs the memory device 1 to output the input/output signal DQ. The memory device 1 generates a signal DQS based on the read enable signal REn.

The logic control circuit 12 outputs a ready/busy signal RBn, which indicates whether the memory device 1 is in a ready state or a busy state, to the memory controller 2.

The register 13 temporarily stores a command CMD, an address ADD, and status information STA. The command CMD includes, for example, an instruction to cause the sequencer 14 to execute a read operation, a write operation, an erasing operation, or the like. The address ADD includes, for example, a block address BA, a page address PA, and a column address CA. For example, the block address BA, the page address PA, and the column address CA are used to select a block BLK, a word line, and a bit line, respectively. The status information STA is updated under the control of the sequencer 14 and transferred to the input/output circuit 11.

The sequencer 14 controls the overall operation of the memory device 1. For example, the sequencer 14 controls the driver module 15, the row decoder module 16, the sense amplifier module 17, or the like based on the command CMD stored in the register 13. This allows a read operation, a write operation, an erasing operation, or the like to be executed.

The driver module 15 generates a plurality of different voltages of different magnitudes that are used in the read operation, the write operation, the erasing operation, or the like. The driver module 15 supplies the generated voltage to the row decoder module 16, the sense amplifier module 17, or the like. The driver module 15 applies the generated voltage to a signal line corresponding to a word line selected based on, for example, a page address PA stored in the register 13. For example, the driver module 15 includes a negative voltage generating circuit 150. The negative voltage generating circuit 150 generates a negative voltage lower than 0 V.

The row decoder module 16 selects one corresponding block BLK in the memory cell array 10 based on, for example, a block address BA stored in the register 13. The row decoder module 16 transfers, for example, a voltage supplied to a signal line by the driver module 15 to a selected word line in a selected block BLK.

The sense amplifier module 17 includes a sense amplifier capable of determining data based on the voltage of an associated bit line, a data latch circuit for temporarily storing data, and the like. In a write operation, the sense amplifier module 17 applies a desired voltage to each bit line in accordance with the write data DAT transferred from the input/output circuit 11. Furthermore, in a read operation, the sense amplifier module 17 determines the data stored in the memory cell based on the presence or absence of discharge of the bit line or the magnitude of the voltage on the bit line. Thereafter, the sense amplifier module 17 transfers the determination result to the input/output circuit 11 as read data DAT.

Hereinafter, the set (circuit group) of circuits 11, 12, 13, 14, 15, 16, and 17 other than the memory cell array 10 in the memory device 1 will be referred to as a CMOS circuit (or a control circuit).

### (a-1-2) Circuit Configuration of Memory Cell Array

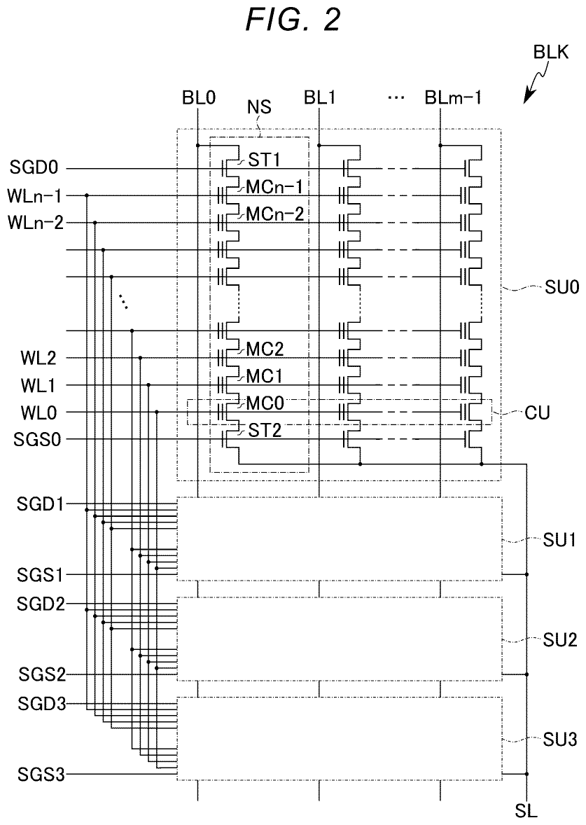

FIG. 2 is a circuit diagram showing a configuration example of a memory cell array in the memory device 1 of the present embodiment. In FIG. 2, the circuit configuration of a certain block BLK in the memory cell array 10 is shown as an example.

As shown in FIG. 2, the block BLK includes, for example, four string units SU0, SU1, SU2, and SU3. Each string unit SU is, for example, a collection of a plurality of NAND strings (memory strings) NS that are collectively selected in a write operation or a read operation. Each string unit SU includes a plurality of NAND strings NS associated with bit lines BL0, BL1, . . . , BLm-1, respectively. Here, m is an integer of 1 or more. The NAND string NS is a set of a plurality of memory cells MC (MC0, MC1, MC2, . . . , MCn-2, MCn-1) connected in series. Each NAND string NS includes, for example, memory cells MC0, MC1, MC2, . . . , MCn-2, MCn-1, a select transistor ST1, and a select transistor ST2. Here, n is an integer of 1 or more.

A memory cell (also called a memory cell transistor) MC is a field effect transistor including a control gate and a charge storage layer.

The select transistors ST1 and ST2 are switching elements. Each of the select transistors ST1 and ST2 is used to select a string unit SU during various operations.

In each NAND string NS, memory cells MC0, . . . , MCn-1 are connected in series. The drain of the select transistor ST1 is connected to an associated bit line BL. The source of the select transistor ST1 is connected to one end of the memory cells MC0, . . . , MCn-1 connected in series. The drain of the select transistor ST2 is connected to the other end of the memory cells MC0, . . . , MCn-1 connected in series. The source of the select transistor ST2 is connected to a source line SL.

In the same block BLK, the control gates of memory cells MC0, MC1, MC2, . . . , MCn-2, MCn-1 are connected in common to word lines WL0, WL1, WL2, . . . , WLn-2, WLn-1, respectively, among the plurality of NAND strings NS.

The gate of the select transistor ST1 in each of the string units SU0, SU1, SU2, and SU3 is connected to corresponding one of a plurality of drain-side select gate lines SGD0, SGD1, SGD2, and SGD3 in common among the plurality of NAND strings NS.

The gate of the select transistor ST2 in each of the string units SU0, SU1, SU2, and SU3 is connected to corresponding one of a plurality of source-side select gate lines SGS0, SGS1, SGS2, and SGS3 in common among the plurality of NAND strings NS.

Hereinafter, when the drain-side select gate lines SGD (SGD0, SGD1, SGD2, SGD3) and the source-side select gate lines SGS (SGS0, SGS1, SGS2, SGS3) are not distinguished, they will be referred to as select gate lines SG.

In the circuit configuration of the memory cell array 10 described above, the bit line BL is shared by, for example, the NAND strings NS to which the same column address is assigned in each string unit SU. The source line SL is shared by, for example, a plurality of string units SU and a plurality of blocks BLK.

In the following, in a certain string unit SU, a set CU of memory cells MC commonly connected to the same word line WL is also referred to as a cell unit CU.

The memory cell MC stores one or more bits of data. A memory cell MC that stores 1-bit data is called a Single Level cell (SLC). A memory cell MC that stores 2-bit data is called a Multi Level cell (MLC). A memory cell MC that stores 3-bit data is called a Triple Level cell (TLC). A memory cell MC that stores 4-bit data is called a Quad Level cell (QLC). A memory cell MC that stores 5-bit data is called a Penta level cell (PLC).

In this example, one memory cell MC stores 3-bit data. Hereinafter, the 3-bit data is referred to as a lower bit, a middle bit, and an upper bit, from the least significant bit. A set of lower bits stored by memory cells MC belonging to the same cell unit CU is called a lower page (or lower data), a set of middle bits is called a middle page (or middle data), and a set of upper bits is called an upper page (or upper data).

When one memory cell MC can store 3-bit data, three pages are assigned to one word line WL (one cell unit CU) in one string unit SU. A “page” can also be defined as a portion of a memory space formed in a cell unit CU. Data may be written and read for each page or for each cell unit CU.

The number of string units SU in the block BLK is any number.

### (a-1-3) Relationship Between Threshold Voltage and Data of Memory Cell

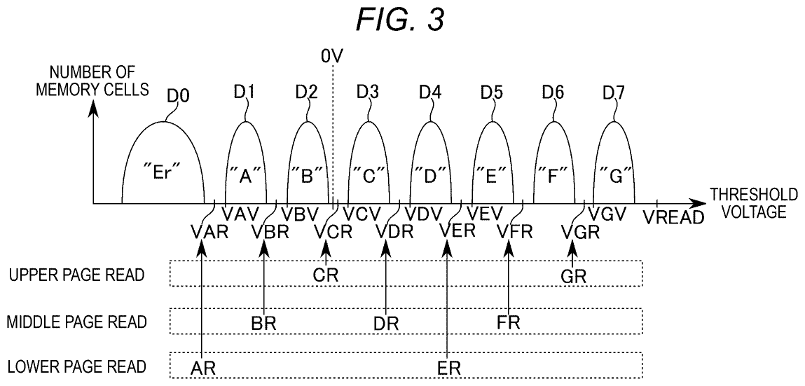

With reference to FIG. 3, the relationship between the threshold voltage of the memory cell MC and the data stored in the memory cell MC in the memory device 1 of the present embodiment will be described.

FIG. 3 is a schematic diagram illustrating the relationship between data stored in a memory cell MC and the threshold voltage distribution of the memory cell MC. FIG. 3 shows possible data for each memory cell MC, a threshold voltage distribution, and a voltage used when reading data. FIG. 3 shows an example in which the memory cell MC is a TLC.

As shown in FIG. 3, when the memory cell MC is capable of storing 3-bit data, the memory cell MC can take eight states (threshold voltage distributions) D0, D1, . . . , D7 depending on the threshold voltage. The eight states are called, in order from lowest threshold voltage, “Er” state D0, “A” state D1, “B” state D2, “C” state D3, “D” state D4, “E” state D5, “F” state D6, and “G” state D7.

The read voltages include a plurality of voltages (hereinafter referred to as read levels) VAR, VBR, VCR, VDR, VER, VFR, and VGR depending on the page to be read. The read level is a voltage for determining whether the threshold voltage of the memory cell MC is equal to or higher than a certain voltage or lower than a certain voltage. By applying the read level, the memory cell MC is turned on or off.

The threshold voltage of the memory cell MC in the “Er” state D0 is lower than the read level VAR, and corresponds to the erased state of data. The threshold voltage of the memory cell MC in the “A” state D1 is equal to or higher than the read level VAR and lower than the read level VBR. The threshold voltage of the memory cell MC in the “B” state S2 is equal to or higher than the read level VBR and lower than the read level VCR. The threshold voltage of the memory cell MC in the “C” state D3 is equal to or higher than the read level VCR and lower than the read level VDR. The threshold voltage of the memory cell MC in the “D” state D4 is equal to or higher than the read level VDR and lower than the read level VER. The threshold voltage of the memory cell MC in the “E” state D5 is equal to or higher than the read level VER and lower than the read level VFR. The threshold voltage of the memory cell MC in the “F” state D6 is equal to or higher than the read level VFR and lower than the read level VGR. The threshold voltage of the memory cell MC in the “G” state D7 is equal to or higher than the read level VGR and lower than the voltage VREAD. The relationship between the read level VAR to the read level VGR and the voltage VREAD is VAR<VBR<VCR<VDR<VER<VFR<VGR<VREAD.

Among the eight states D0, . . . , D7 distributed in this manner, the “G” state D7 is the state in which the threshold voltage of the memory cell is the highest. Each state D0, . . . , D7 has a range of voltage values associated with the corresponding data.

The voltage VREAD is, for example, a voltage applied to a word line (non-selected word line) WL that is not the read target during a read operation. When the voltage VREAD is applied to a memory cell MC, the memory cell MC is turned on regardless of the data stored in the memory cell MC.

For example, the memory cells MC in the “Er” state D0, the “A” state D1, or the “B” state D2 among the eight states D0, . . . , D7 have a negative threshold voltage less than 0 V. The memory cells MC in the “C” state D3, the “D” state D4, the “E” state D5, the “F” state D6, or the “G” state D7 have a positive threshold voltage equal to or greater than 0 V. In this case, the read levels VAR and VBR have negative voltage values, and the read levels VCR, VDR, VER, VFR, and VGR and the voltage VREAD have positive voltage values.

The threshold voltage distribution is formed by writing 3-bit (three pages) data including the lower bit, middle bit, and upper bit described above into memory cells MC in the memory cell array 10. An example of the relationship between the threshold voltage states and the upper, middle, and lower bits is as follows.

“Er” state: “111” (written in the order of
“upper/middle/lower”)
“A” state: “110”
“B” state: “100”
“C” state: “000”
“D” state: “010”
“E” state: “011”
“F” state: “001”
“G” state: “101”

In this way, only one bit out of three bits changes between data corresponding to two adjacent states in the threshold voltage distribution.

To read the lower bit of the memory cell MC, a voltage corresponding to the boundary at which the value (“0” or “1”) of the lower bit changes is used. To read the upper bit of the memory cell MC, a voltage corresponding to the boundary at which the value of the upper bit changes is used. To read the middle bit, a voltage corresponding to the boundary at which the value of the middle bit changes is used.

To read the lower bit of the memory cell MC, the memory device 1 reads the lower page of the cell unit CU. As shown in FIG. 3, reading of the lower page is performed using as the read voltage, the read level VAR that distinguishes between “Er” state D0 and “A” state D1, and the read level VER that distinguishes between “D” state V4 and “E” state D5.

To read the middle bit of the memory cell MC, the memory device 1 reads the middle page of the cell unit CU. Reading of the middle page is performed using as the read voltage, the read level VBR that distinguishes between “A” state D1 and “B” state D2, the read level VDR that distinguishes between “C” state D3 and “D” state D4, and the read level VFR that distinguishes between “E” state D5 and “F” state D6.

To read the upper bit of the memory cell MC, the memory device 1 reads the upper page of the cell unit CU. Reading of the upper page is performed using as the read voltage, the read level VCR that distinguishes between “B” state D2 and “C” state D3, and the read level VGR that distinguishes between “F” state D6 and “G” state D7.

The memory cells MC in the erased state are identified by reading using the read level VAR.

In the following, reading (determination) using the read level VAR is also called AR reading. Similarly, reading using the read levels VBR, VCR, VDR, VER, VFR, and VGR are called BR reading, CR reading, DR reading, ER reading, FR reading, and GR reading, respectively.

For example, a plurality of verification levels VAV, VBV, VCV, VDV, VEV, VFV, and VGV used in the verification operation of the write operation are provided between the lower limit of each threshold voltage distribution D1, D2, D3, D4, D5, D6, and D7 and each read level VAR, VBR, VCR, VDR, VER, VFR, and VGR, respectively. The state of the threshold voltage of the memory cell MC during a write operation is verified based on the result of turning the memory cell MC on or off in response to application of each verification level VAV, VBV, VCV, VDV, VEV, VFV, and VGV.

### (a-2) Structure

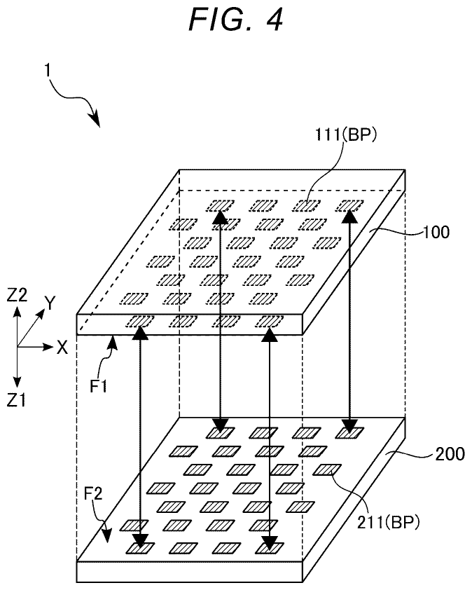

The structure of the memory device of the present embodiment will be described with reference to FIGS. 4 to 9.

### (a-2-1) Memory Device Structure

The structure example of the memory device 1 of the present embodiment will be described with reference to FIG. 4.

FIG. 4 is a bird's-eye view showing the structure example of the memory device 1 of the present embodiment.

As shown in FIG. 4, the memory device 1 of the present embodiment has a bonding structure. The memory device 1 of the present embodiment includes two semiconductor chips 100 and 200 that are bonded together.

One of the two semiconductor chips 100 and 200 is a memory cell array chip 100. The memory cell array chip 100 is a chip on which a memory cell array 10 is provided.

The other of the two semiconductor chips 100 and 200 is a CMOS circuit chip 200. The CMOS circuit chip 200 is a chip provided with a CMOS circuit that controls the memory cell array chip 100.

Note that a plurality of memory cell array chips 100 may be provided within the memory device 1. In this case, the plurality of memory cell array chips 100 may be stacked on and bonded to the CMOS circuit chip 200. A plurality of CMOS circuit chips 200 may be provided within the memory device 1.

As shown in FIG. 4, the memory cell array chip 100 includes a plurality of pads 111 on a face F1. The CMOS circuit chip 200 includes a plurality of pads 211 on a face F2. The pads 111 and 211 are used to bond the two chips 100 and 200 together.

In the memory device 1 having a bonding structure, the face F1 of the memory cell array chip 100 is bonded to the face F2 of the CMOS circuit chip 200. In this manner, the face F1 of the memory cell array chip 100 on which the pads 111 are provided faces the face F2 of the CMOS circuit chip 200 on which the pads 211 are provided.

In the bonding structure, the pads 111 of the memory cell array chip 100 and the pads 211 of the CMOS circuit chip 200 are bonded together. Thus, one bonding pad BP is formed in the memory device 1. In other words, an electrode configuring the pad 111 provided on the memory cell array chip 100 is joined to an electrode configuring the pad 211 provided on the CMOS circuit chip 200. In this manner, the bonding pads BP of the memory device 1 having a bonding structure are formed.

### (a-2-2) Memory Cell Array Structure

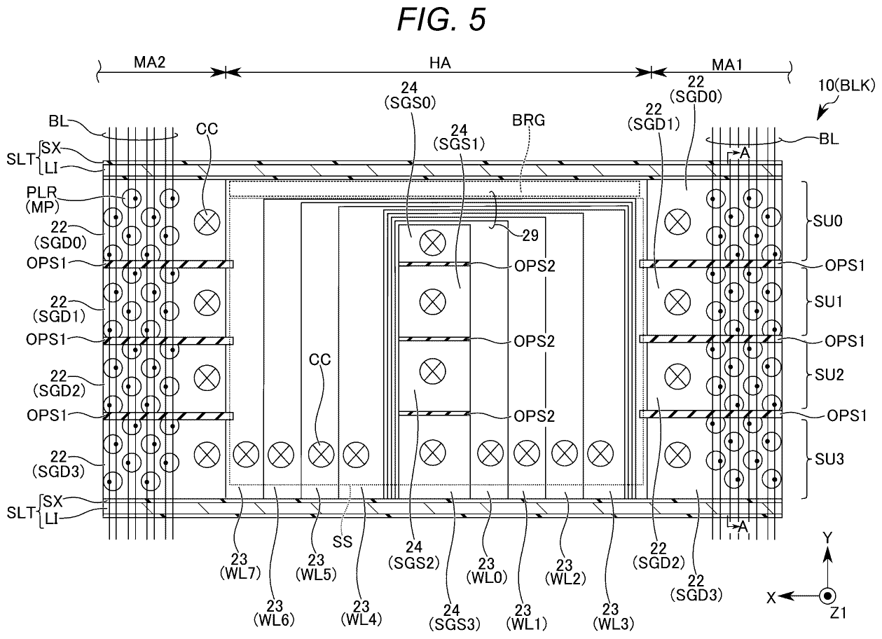

A structure example of the memory cell array 10 of the memory device 1 of the present embodiment will be described with reference to FIGS. 5 to 9.

FIG. 5 is a plan view showing the structure example of the memory cell array 10 in the memory device 1 of the present embodiment. In FIG. 5, a portion of a certain block BLK in the memory cell array 10 is extracted and shown.

As shown in FIG. 5, the memory cell array 10 is divided in the X direction into two memory areas MA1 and MA2 and a hook-up area HA. The hook-up area HA is provided between the memory area MA1 and the memory area MA2.

The memory areas MA1 and MA2 are areas that include NAND strings NS used to store data. The memory areas MA1 and MA2 include a plurality of wiring layers (conductive layers) 22, 23, and 24 stacked and spaced apart in the Z direction. The plurality of wiring layers 22, 23 and 24 are led out from the memory areas MA1 and MA2 to the hook-up area HA. The plurality of wiring layers 22, 23, and 24 correspond to the word lines WL and the select gate lines SG. In the following, an example in which the number of word lines WL in a block BLK is eight will be shown.

The hook-up area HA is an area used for connection between the plurality of wiring layers 22, 23, and 24 and the row decoder module 16.

Members SLT, OPS1, and OPS2 are provided in the memory cell array 10.

Each of the plurality of members SLT extends along the X direction. The plurality of members SLT are aligned in the Y direction. Each member SLT is provided in a boundary area between adjacent blocks BLK. The member SLT crosses the memory areas MA1 and MA2 and the hook-up area HA in the X direction. An area partitioned by the members SLT corresponds to one block BLK in the memory cell array 10. Each member SLT has a structure in which, for example, a plate-like contact LI and a spacer SX are embedded. The member SLT divides the wiring layers 22, 23, and 24 adjacent to each other with the member SLT interposed therebetween.

A plurality of members OPS1 are provided in each of the memory areas MA1 and MA2. Each of the plurality of members OPS1 in the memory area MA1 crosses the memory area MA1 in the X direction. The plurality of members OPS1 in the memory area MA1 are aligned in the Y direction. Each of the plurality of members OPS1 in the memory area MA2 crosses the memory area MA2 in the X direction. The plurality of members OPS1 in the memory area MA2 are aligned in the Y direction. For example, the end of each member OPS1 on the hook-up area HA side is disposed within the hook-up area HA.

For example, in each of the memory areas MA1 and MA2, three members OPS1 are disposed between members SLT adjacent to each other in the Y direction. A combination of each of the areas partitioned by the members SLT and OPS1 in the memory area MA1 and each of the areas partitioned by the members SLT and OPS1 in the memory area MA2 corresponds to one string unit SU in the memory cell array 10. Each member OPS1 is, for example, a structure including an insulator embedded in a slit. Each member OPS1 divides the adjacent wiring layers 22 via this member OPS1. Each wiring layer 22 corresponds to a drain-side select gate line SGD.

A plurality of members OPS2 are provided in each of the memory areas MA1 and MA2. Each of the plurality of members OPS2 in the memory area MA1 crosses the memory area MA1 in the X direction. The plurality of members OPS2 in the memory area MA1 are aligned in the Y direction. Each of the plurality of members OPS2 in the memory area MA2 crosses the memory area MA2 in the X direction. The plurality of members OPS2 in the memory area MA2 are aligned in the Y direction. For example, each member OPS2 extends from the memory areas MA1 and MA2 into the hook-up area HA. Each member OPS2 is continuous between the memory areas MA1 and MA2 via the hook-up area HA.

For example, in each of the memory areas MA1 and MA2, three members OPS2 are disposed between members SLT adjacent to each other in the Y direction. A combination of each of the areas partitioned by the members SLT and OPS2 in the memory area MA1 and each of the areas partitioned by the members SLT and OPS2 in the memory area MA2 corresponds to one string unit SU in the memory cell array 10. Each member OPS2 is, for example, a structure including an insulator embedded in a slit. Each member OPS2 divides the wiring layers 24 adjacent to each other with this member OPS2 interposed therebetween. Each wiring layer 24 corresponds to a source-side select gate line SGS.

A plurality of wiring layers 23 are led out from the memory areas MA1 and MA2 to the hook-up area HA. Each wiring layer 23 corresponds to a word line WL.

A plurality of pillar portions PLR are provided in the memory areas MA1 and MA2. Each of the plurality of pillar portions PLR includes a memory pillar MP. Each memory pillar MP extends in the Z direction. Each memory pillar MP penetrates the plurality of wiring layers 22, 23, and 24. The memory pillars MP are laid out in a staggered arrangement in the XY plane of the memory areas MA1 and MA2. A set of memory pillars MP aligned on the same straight line in the X direction forms a row.

A plurality of bit lines BL are provided above the memory areas MA1 and MA2 in the Z direction. The plurality of bit lines BL are aligned in the X direction. Each bit line BL extends in the Y direction. Each bit line BL is electrically connected to a corresponding memory pillar MP via a contact CV in each string unit SU.

It should be noted that the planar layout of the memory cell array 10 of the memory device 1 of the present embodiment is not limited to the above-described layout. For example, the number of members OPS1 and OPS2 disposed between two members SLT can be designed to be any number depending on the number of string units SU in the block BLK.

The hook-up area HA is provided between two memory areas MA1 and MA2 aligned in the X direction. The hook-up area HA includes a staircase portion SS and a bridge portion BRG. Between the two members SLT aligned in the Y direction, the staircase portion SS is aligned with the bridge portion BRG in the Y direction.

In the staircase portion SS, a set of the plurality of wiring layers 22, 23, and 24 has a structure processed into a staircase shape (hereinafter, also referred to as a staircase structure). Each of the wiring layers 22, 23, and 24 has an exposed portion (hereinafter referred to as a terrace portion) that is not covered by an upper wiring layer. Contacts (contact plugs) CC are provided on the terraces of the wiring layers 22, 23, and 24. Each of the wiring layers 22, 23, and 24 is electrically connected to a corresponding wiring of the row decoder module 16 via the contact CC.

The bridge portion BRG includes a plurality of wiring layers 29 that electrically connect the wiring layers 22, 23, and 24 in the memory area MA1 and the wiring layers 22, 23, and 24 in the memory area MA2. For example, each wiring layer 29 in the bridge portion BRG is continuous with the wiring layers 22, 23, and 24 in the memory area MA1 and the wiring layers 22, 23, and 24 in the memory area MA2.

For example, the wiring layer 24 serving as the source-side select gate line SGS is continuous between the memory area MA1 and the memory area MA2 via the hook-up area HA.

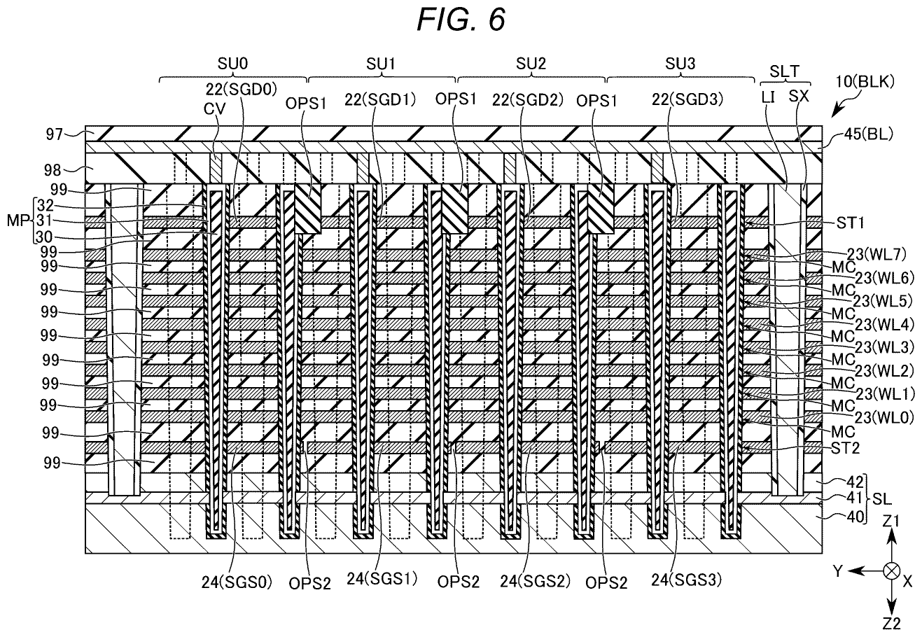

FIG. 6 is a cross-sectional view showing a structure example of the memory cell array 10 in the memory device 1 of the present embodiment. FIG. 6 shows a cross-sectional structure of the memory cell array 10 taken along line A-A in FIG. 5. In FIG. 6, members in the depth direction or front direction of the drawing are indicated by dashed lines.

In the following description, the Z1 direction is the upward direction, and the Z2 direction is the downward direction. Furthermore, when the Z1 direction and the Z2 direction are not distinguished, each of the Z1 direction and the Z2 direction is called the Z direction.

As shown in FIG. 6, the memory cell array 10 includes a plurality of wiring layers 22, 23, and 24 stacked in the Z direction. Each of the plurality of wiring layers 22, 23, and 24 includes, for example, a stacked film of tungsten (W) and titanium nitride (TiN).

The plurality of wiring layers 24 are provided on the wiring layers 42 that form the source lines SL, with an insulating layer 99 interposed therebetween. The plurality of wiring layers 24 are aligned in the Y direction. The plurality of wiring layers 24 function as a plurality of source-side select gate lines SGS that are independent of each other. For example, when four string units SU are set in one block BLK, the number of wiring layers 24 in each of the memory areas MA1 and MA2 is four. Hereinafter, the wiring layer 24 is also referred to as a source-side select gate line layer 24.

The plurality of wiring layers 23 are provided between the plurality of wiring layers 22 and the plurality of wiring layers 24 in the Z direction. The insulating layer 99 is provided between two wiring layers 23 stacked in the Z direction. The wiring layers 23 and the insulating layers 99 are alternately stacked above the plurality of wiring layers 24. Thus, the plurality of wiring layers 23 are spaced apart from one another. Each of the plurality of wiring layers 23 functions as a word line WL. When one block BLK includes eight word lines WL, the number of wiring layers 23 is eight. Hereinafter, the wiring layer 23 will also be referred to as a word line layer 23.

The plurality of wiring layers 22 are provided above the plurality of wiring layers 23 in the Z direction with an insulating layer 99 interposed therebetween. The plurality of wiring layers 22 are aligned in the Y direction. The plurality of wiring layers 22 function as a plurality of drain-side select gate lines SGD that are independent of each other. For example, when four string units SU are set in one block BLK, the number of wiring layers 22 in each of the memory areas MA1 and MA2 is four. Hereinafter, the wiring layer 22 is also called a drain-side select gate line layer 22.

The source line SL includes a plurality of wiring layers (conductive layers) 40, 41, and 42 that are stacked. The plurality of wiring layers 40, 41, and 42 are provided below the wiring layer 24 in the Z direction. The wiring layer 41 is provided between the two wiring layers 40 and 42 in the Z direction. The wiring layers 40, 41, and 42 contain silicon doped with phosphorus. Hereinafter, the set SL of the plurality of wiring layers (conductive layers) 40, 41, and 42 is also referred to as a source line layer SL.

A plurality of memory pillars MP are provided in a plurality of stacked wiring layers 22, 23, and 24. Each memory pillar MP penetrates the plurality of wiring layers 22, 23, and 24. The end of each memory pillar MP in the Z2 direction is provided in the source line layer SL. The memory pillar MP has a tapered structure. The diameter (dimension along the XY plane) of the memory pillar MP on the wiring layer 22 side is larger than the diameter of the memory pillar MP on the wiring layer 24 side.

Each memory pillar MP includes a core layer 30, a semiconductor layer 31, and a memory layer 32. The core layer 30 extends in the Z direction. The semiconductor layer 31 extends in the Z direction to cover the side surfaces of the core layer 30. The memory layer 32 extends in the Z direction to cover the side surface on the outer periphery side of the semiconductor layer 31. The semiconductor layer 31 functions as the channel areas of the memory cells MC and the select transistors ST1 and ST2. The memory layer 32 has electrical properties that change depending on the data to be stored.

The side surfaces of the memory pillar MP face the wiring layers 22, 23, and 24 in the X and Y directions. At the end of the memory pillar MP in the Z2 direction, the semiconductor layer 31 is in contact with the wiring layer 41 of the source line layer SL via an opening formed in the memory layer 32. Thus, the semiconductor layer 31 is electrically connected to the source line SL.

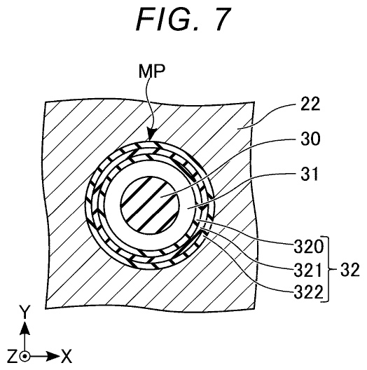

FIG. 7 is a cross-sectional view showing a specific example of a cross-sectional structure of a memory pillar MP along the XY plane (planar shape of the memory pillar MP viewed from the Z direction) at the level of a certain wiring layer 23.

As shown in FIG. 7, the core layer 30 has a circular (or elliptical) planar shape when viewed in the Z direction. The core layer 30 has a cylindrical structure.

The semiconductor layer 31 has a circular ring (or an elliptical ring) planar shape when viewed from the Z direction. The semiconductor layer 31 has a cylindrical structure. In the memory pillar MP, the semiconductor layer 31 is provided between the core layer 30 and the memory layer 32.

The memory layer 32 has a circular ring (or an elliptical ring) planar shape when viewed from the Z direction. The memory layer 32 has a cylindrical structure. The memory layer 32 is a stacked film including a tunnel insulating film 320, a charge storage layer 321, and a block insulating film 322.

The tunnel insulating film 320 is provided between the semiconductor layer 31 and the charge storage layer 321. The charge storage layer 321 is provided between the tunnel insulating film 320 and the block insulating film 322. The block insulating film 322 is provided between the charge storage layer 321 and the wiring layer 23.

In the structure of the memory pillar MP shown in FIG. 7, the portion where the memory pillar MP and the wiring layer (source-side select gate line layer) 24 intersect functions as the select transistor ST2. The portion where the memory pillar MP and the wiring layer (word line layer) 23 intersect functions as a memory cell MC. The portion where the memory pillar MP and the wiring layer (drain-side select gate line layer) 22 intersect functions as a select transistor ST1.

Returning to FIG. 6, the structure of the memory cell array 10 will be described.

An insulating layer 98 is provided above the wiring layer 22. A plurality of wiring layers 45 are provided above the insulating layer 98. An insulating layer 97 is provided above the wiring layer 45. The wiring layer 45 has, for example, a linear structure extending along the Y direction. The wiring layer 45 functions as a bit line BL. In the depth direction or front direction of the drawing, the plurality of wiring layers 45 are aligned along the X direction. The wiring layer 45 contains, for example, copper. Each of the wiring layers 45 is electrically connected to a corresponding one of the plurality of memory pillars MP belonging to each string unit SU.

A plurality of contacts CV are embedded in the insulating layer 98. Each contact CV comes into contact with the upper surface of the semiconductor layer 31 in the memory pillar MP. Each contact CV electrically connects a certain memory pillar MP to one wiring layer 45 (bit line BL).

The member SLT is formed to extend along the XZ plane, for example. The member SLT penetrates the plurality of wiring layers 22, 23, and 24 and the plurality of insulating layers 99. The end of the member SLT in the Z2 direction reaches the source line layer SL.

The contact LI of the member SLT is provided so as to extend along the XZ plane. The spacer SX of the member SLT is provided between the contact LI and the wiring layers 22, 23, and 24. The end (upper end) of the contact LI in the Z1 direction is located in, for example, the uppermost insulating layer 99. The end (lower end) of the contact LI in the Z2 direction is in contact with, for example, the conductive layer 41 of the source line layer SL. Furthermore, the contact LI may be omitted depending on the structure of the memory cell array 10.

The member OPS1 has, for example, a plate-like structure extending along the XZ plane. The member OPS1 divides the wiring layers 22 adjacent to each other in the Y direction. The member OPS1 is provided in the boundary area between the string units SU. The end (lower end) of the member OPS1 in the Z2 direction is located, for example, in the area between the wiring layer 22 and the uppermost wiring layer 23. The member OPS1 includes an insulator such as silicon oxide. The insulator of the member OPS1 is filled into slits formed in the boundary areas between the string units SU. The member OPS1 overlaps with the end of the memory pillar MP between two wiring layers 22 adjacent to each other in the Y direction.

The member OPS2 has a linear structure extending in the X direction. The member OPS2 divides two wiring layers 24 adjacent to each other in the Y direction. The member OPS2 includes an insulator (insulating layer 99) filled in the slits between the wiring layers 24.

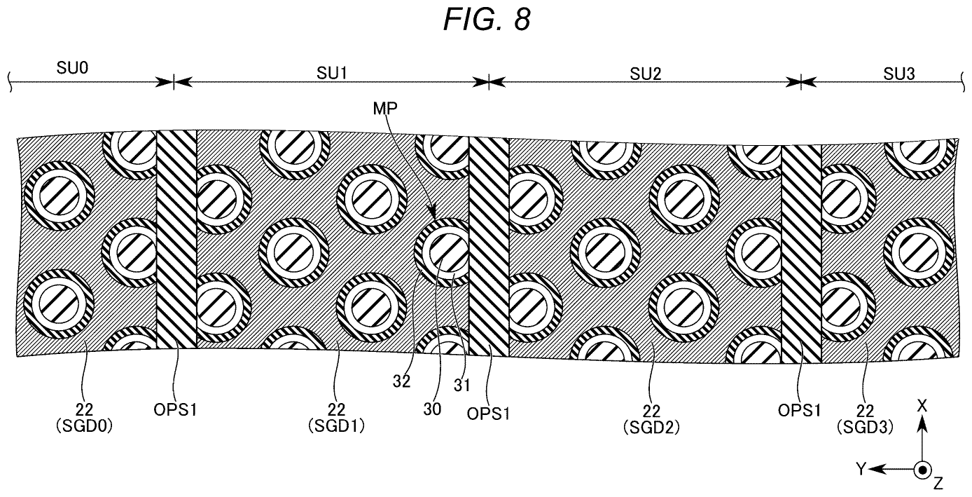

FIG. 8 is a cross-sectional view showing the cross-sectional structure of a memory pillar MP along the XY plane at the hierarchy of the wiring layer 22.

As shown in FIG. 8, each member OPS1 is provided between the wiring layers 22 as the drain-side select gate lines SGD. The member OPS1 separates the plurality of wiring layers 22 from one another. In this manner, the member OPS1 is provided within the boundary between adjacent string units SU.

In the hierarchy of the wiring layer 22, the member OPS1 partially overlaps with the memory pillar MP near the boundary of the string unit SU. The member OPS1 is in direct contact with the memory pillar MP.

The end of the memory pillar MP on the member OPS1 side is chipped off by the member OPS1 (and the process of forming the member OPS1). For example, the semiconductor layer 31 and the memory layer 32 are partially removed from the memory pillar MP. The side surface of the core layer 30 is in contact with the side surface of the member OPS1. In the chipped portion of the memory pillar MP, the semiconductor layer 31 and the memory layer 32 are in contact with the member OPS1. Furthermore, the semiconductor layer 31 may remain between the core layer 30 and the member OPS1.

Thus, within the hierarchy of the wiring layer 22, the upper portion of the memory pillar MP on the boundary of the string unit SU has a planar shape in which an arc is partially chipped off (hereinafter also referred to as a partial circular shape, a half circular shape or a semicircular shape) when viewed from the Z direction. A circular (elliptical) planar shape in which an arc is not chipped off is also referred to as a full circle shape.

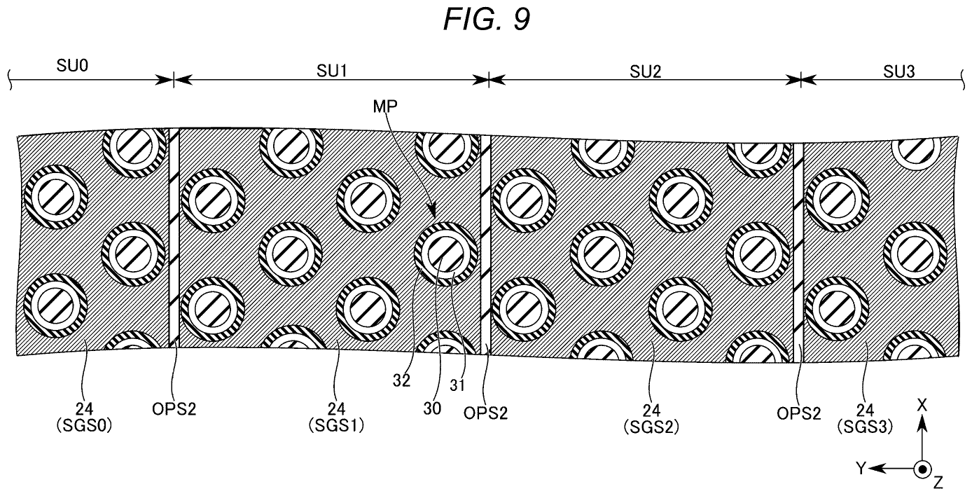

FIG. 9 is a cross-sectional view showing the cross-sectional structure of a memory pillar MP along the XY plane at the hierarchy of the wiring layer 24.

As shown in FIG. 9, in the hierarchy of the wiring layer 24, the member OPS2 passes through the area between the memory pillars MP near the boundary of the string unit SU. For example, the member OPS2 is not in contact with the memory pillar MP.

Furthermore, depending on the manufacturing process of the memory cell array 10, within the hierarchy of the wiring layer 24, the memory pillar MP may have a partial circular shape (half circular shape) in which at least one of the semiconductor layer 31 and the memory layer 32 is partially removed.

The memory device 1 of the present embodiment can be formed by a combination of well-known memory device manufacturing processes.

When performing an operation on the memory cell array 10, the memory device 1 of the present embodiment applies a negative voltage (a voltage less than 0 V) to one or two unselected drain-side select gate lines SGD adjacent to the drain-side select gate line SGD selected corresponding to the string unit SU to be operated from among the plurality of drain-side select gate lines SGD (wiring layer 22).

Hereinafter, the drain-side select gate line selected as the operation target is also referred to as a selected drain-side select gate line SGD-SEL. The unselected drain-side select gate line adjacent to the selected drain-side select gate line SGD-SEL is also referred to as the adjacent drain-side select gate line SGD-USEL1.

In addition, when performing an operation on the memory cell array 10, the memory device 1 of the present embodiment applies a negative voltage (a voltage less than 0 V) to one or two unselected source-side select gate lines SGS adjacent to the source-side select gate line SGS selected corresponding to the string unit SU to be operated from among the plurality of source-side select gate lines SGS.

Hereinafter, the source-side select gate line selected as the operation target is also referred to as a selected source-side select gate line SGS-SEL. The unselected source-side select gate line adjacent to the selected source-side select gate line SGS-SEL is also referred to as the adjacent source-side select gate line SGS-USEL1.

The drain-side select gate lines SGD other than the selected drain-side select gate line SGD-SEL and the adjacent drain-side select gate line SGD-USEL1 are referred to as unselected drain-side select gate lines SGD-USEL2. The source-side select gate lines SGS other than the selected source-side select gate line SGS-SEL and the adjacent source-side select gate line SGS-USEL1 are referred to as unselected source-side select gate lines SGS-USEL2.

The selected drain-side select gate line SGD-SEL and the selected source-side select gate line SGS-SEL belong to the selected string unit SU to be operated. The unselected string unit SU includes a NAND string NS including a memory cell to be operated. The adjacent/unselected drain-side select gate lines SGD-USEL1, SGD-USEL2 and the adjacent/unselected source-side select gate lines SGS-USEL1, SGS-USEL2 belong to an unselected string unit SU that is not to be operated.

In the following, when the selected drain-side select gate line SGD-SEL and the selected source-side select gate line SGS-SEL are not distinguished from each other, they are also referred to as the selected select gate line SG-SEL. When the adjacent drain-side select gate line SGD-USEL1 and the adjacent source-side select gate line SGS-USEL1 are not distinguished, they are also referred to as adjacent select gate line SG-USEL1. When the unselected drain-side select gate lines SGD-USEL2 and the unselected source-side select gate lines SGS-USEL2 are not distinguished, they are also referred to as unselected select gate lines SG-USEL2.

### (a-3) Outline of Operation of Memory Device

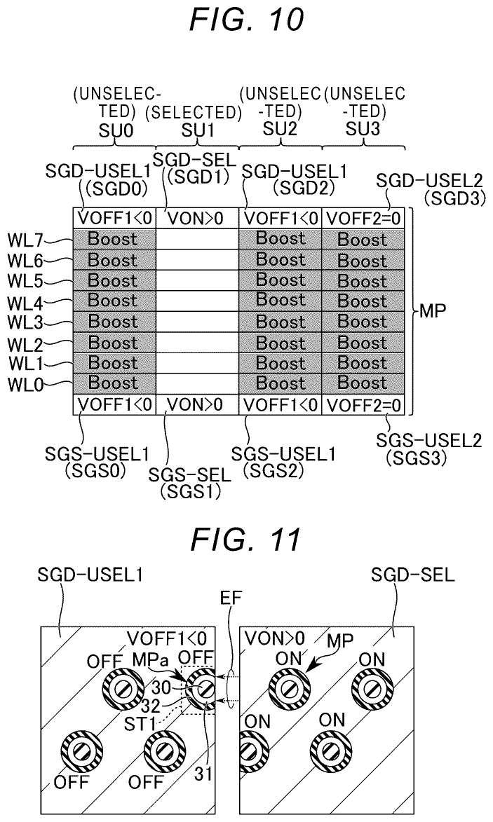

The outline of the operation of the memory device 1 of the present embodiment will be described with reference to FIGS. 10 and 11.

FIGS. 10 and 11 are schematic diagrams illustrating an outline of the operation of the memory device 1 of the present embodiment. FIG. 10 is a schematic diagram showing a state in which voltages are applied to the selected/unselected select gate lines SGD, SGS in the memory cell array 10 during the operation of the memory device 1 of the present embodiment. FIG. 11 is a schematic diagram showing the state of the memory pillar MP of the adjacent drain-side select gate line SGD-USEL1 during the operation of the memory device 1 of the present embodiment.

As shown in FIG. 10, when performing an operation, the memory device 1 applies a voltage (selection voltage) VON having a positive voltage value to the selected drain-side select gate line SGD-SEL and the selected source-side select gate line SGS-SEL. In the example of FIG. 10, the string unit SU1 is selected, and the drain-side select gate line SGD1 and the source-side select gate line SGS1 are set to the selected drain-side select gate line SGD-SEL and the selected source-side select gate line SGS-SEL.

The memory device 1 applies a voltage (non-selection voltage) VOFF1 having a negative voltage value to the adjacent drain-side select gate line SGD-USEL1 and the adjacent source-side select gate line SGS-USEL1. In the string units SU0 and SU2, the drain-side select gate lines SGD0 and SGD2 are set to the adjacent drain-side select gate line SGD-USEL1, and the source-side select gate lines SGS0 and SGS2 are set to the adjacent source-side select gate line SGS-USEL1. The voltage VOFF1 has a voltage value within the range of −2.5 V to −1.5 V. For example, the voltage VOFF1 is −2.0 V. However, the voltage value of the voltage VOFF1 may be lower than −2.5 V or higher than −1.5 V as long as it is lower than 0 V. For example, the voltage value of the voltage VOFF1 is different from the read levels VAR and VBR, which have negative voltage values. Note that the voltage value of the voltage VOFF1 applied to the adjacent source-side select gate line SGS-USEL1 may be different from the voltage value of the voltage VOFF1 applied to the adjacent drain-side select gate line SGD-USEL1, as long as it is a negative voltage value.

The memory device 1 applies, for example, a voltage of 0 V (non-selection voltage) VOFF2 to the unselected drain-side select gate line SGD-USEL2 and the unselected source-side select gate line SGS-USEL2. The drain-side select gate line SGD3 and the source-side select gate line SGS3 of the string unit SU3 are set to the unselected drain-side select gate line SGD-USEL2 and the unselected source-side select gate line SGS-USEL2.

The memory device 1 applies various voltages for execution on the selected memory cells MC to the plurality of word lines WL.

As shown in FIG. 11, when a positive voltage VON is applied to the selected drain-side select gate line SGD-SEL, an electric field EF is generated from the selected select gate line SGD-SEL. The generated electric field EF is applied to a memory pillar MP of a partial circular shape near the boundary of the string unit SU (the boundary between adjacent wiring layers 22). An electric field EF is applied to the semiconductor layer 31 of the memory pillar MP of a partial circular shape via the insulator of the member OPS1.

When a voltage of 0 V is applied to the adjacent drain-side select gate line SGD-USEL1, there is a possibility that the select transistor ST1 formed from the memory pillar MPa of a partial circular shape is weakly turned on by the electric field from the selected select gate line SGD-SEL. The select transistor ST1 in a weak on state causes a leakage (leakage current) to occur in the memory pillar MP connected to the adjacent drain-side select gate line SGD-USEL1. Due to the occurrence of this leakage, the capacitor between the memory pillar MP and the wiring layer (word line) 23 affects the operation of the memory device 1.

In the memory device 1 of the present embodiment, during the operation of the memory device 1, the negative voltage VOFF1 less than 0 V is applied to the adjacent drain-side select gate line SGD-USEL1. By applying a negative voltage, the semiconductor layer 31 of the select transistor ST1 enters an accumulation state, in the memory pillar MPa having an upper portion of a partial circular shape connected to the adjacent drain-side select gate line SGD-USEL1.

Thus, even when the electric field EF generated from the selected select gate line SGD-SEL is applied to the memory pillar MPa connected to the adjacent drain-side select gate line SGD-USEL1, the effect of the electric field EF on the memory pillar MP is reduced (for example, offset).

Therefore, in the adjacent drain-side select gate line SGD-USEL1, the select transistor ST1 on the memory pillar MPa of a partial circular shape is cut off without being in a weak on state.

As a result, leakage is reduced in the memory pillars MP and MPa connected to the adjacent drain-side select gate line SGD-USEL1. Therefore, the effect of the capacitor between the memory pillar MP and the wiring layer 22 is reduced. Therefore, in the memory device 1 of the present embodiment, leakage of the channel boost of the memory pillar MP is reduced.

As described above, in the source-side select gate line SGS, similarly to the drain-side select gate line SGD, when a positive voltage VON is applied to the selected source-side select gate line SGS-SEL, the negative voltage VOFF1 is applied to the adjacent source-side select gate line SGS-USEL1. This reduces the weak on state of the select transistor ST2 connected to the adjacent source-side select gate line SGS-USEL1 in response to the electric field EF from the selected source-side select gate line SGS-SEL. Therefore, leakage from the select transistor ST2 connected to the adjacent source-side select gate line SGS-USEL1 is reduced. Therefore, the semiconductor layer 31 in the memory pillar MP is channel boosted in a state in which the capacitor between the memory pillar MP and the wiring layer 22 is reduced.

In this manner, the memory pillars MP and MPa connected to the adjacent select gate lines SGD-USEL1 and SGS-USEL1 are electrically isolated from the bit lines BL and source lines SL.

Therefore, as shown in FIG. 10, in string units SU (for example, string units SU0 and SU1) including adjacent select gate lines SGD-USEL1, SGS-USEL1, the inside of the semiconductor layer (channel) 31 of the memory pillar MP is boosted without being affected by leakage.

In this way, during operation of the memory device 1, in the string unit SU including the adjacent select gate lines SGD-USEL1 and SGS-USEL1, the effect of the capacitor between the memory pillar MP and the word line WL is reduced.

That is, in the memory device 1 of the present embodiment, only the capacitor between the memory pillar MP and the word line WL of the selected string unit SU needs to be charged.

Therefore, in the memory device 1 of the present embodiment, the charging current of the word lines WL during the operation of the memory device 1 can be reduced. By reducing the charging current, in the memory device 1 of the present embodiment, the charging speed (operating speed) of the wiring layer 23 (word line WL) can be improved.

### (b) Operation Example

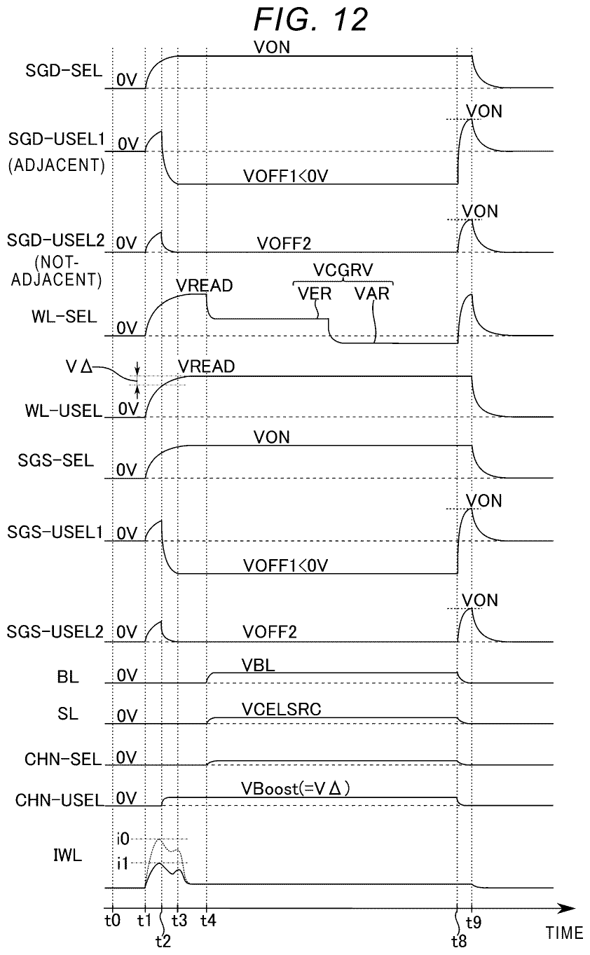

With reference to FIG. 12, an example of the operation of the memory device 1 of the present embodiment will be described. It should be noted that the operation of the memory device may include a method of controlling the memory device.

FIG. 12 is a timing chart (waveform diagram) showing an example of the operation of the memory device 1 of the present embodiment. In FIG. 12, the horizontal axis corresponds to time, and the vertical axis corresponds to the voltage value or current value of each wiring. FIG. 12 shows a read operation of the memory device 1 as an example of the operation of the memory device 1 of the present embodiment.

### Time t0

As shown in FIG. 12, at time t0, the memory device 1 starts a read operation on the operation target indicated by the address ADD based on the command CMD from the memory controller 2. The driver module 15 generates various voltages to be supplied to each wiring of the memory cell array 10.

The memory device 1 applies a predetermined voltage to each wiring under the control of the sequencer 14.

### Time t1

At time t1, the memory device 1 starts applying voltages to a plurality of wirings WL, SGD, and SGS in a block BLK (hereinafter, referred to as a selected block) selected based on the address ADD. This changes the voltages of the plurality of wirings WL, SGD, and SGS in the selected block BLK.

For example, the memory device 1 applies a non-selection voltage VREAD to the selected word line WL-SEL and the non-selected word line WL-USEL. The memory device 1 applies a voltage VON to the selected drain-side select gate line SGD-SEL, the unselected drain-side select gate lines SGD-USEL1 and SGD-USEL2, the selected source-side select gate line SGS-SEL, and the unselected source-side select gate lines SGS-USEL1 and SGS-USEL2.

The voltages of the plurality of word lines WL-SEL and WLU-SEL rise to a positive voltage value. The voltages of the plurality of drain-side select gate lines SGD-SEL, SGD-USEL1, and SGD-USEL2 rise to a positive voltage value. The voltages of the plurality of source-side select gate lines SGS-SEL, SGS-USEL1, and SGS-USEL2 rise to a positive voltage value.

In response to application of voltages to the word line WL and the select gate lines SGD and SGS, a charging current IWL for the word line WL is generated. The current value of the charging current IWL rises. For example, the magnitude of the charging current IWL reaches a current value (peak value) i1 between time t1 and time t2.

### Time t2

At time t2, the voltages of the drain-side select gate lines SGD-SEL, SGD-USEL1, and SGD-USEL2 and the voltages of the source-side select gate lines SGS-SEL, SGS-USEL1, and SGS-USEL2 reach a certain voltage value. The memory device 1 stops applying the positive voltage to the unselected drain-side select gate lines SGD-USEL1 and SGD-USEL2 and the unselected source-side select gate lines SGS-USEL1 and SGS-USEL2. Incidentally, “stopping the application of voltage” includes applying a voltage of 0 V.

At time t2, the memory device 1 starts applying the negative voltage VOFF1 to one or two adjacent drain-side select gate lines SGD-USEL1 of the unselected drain-side select gate lines SGD-USEL1 and SGD-USEL2. The memory device 1 starts applying the negative voltage VOFF1 to one or two adjacent source-side select gate line SGS-USEL1 among the unselected source-side select gate lines SGS-USEL1 and SGS-USEL2. Thus, the adjacent drain-side select gate line SGD-USEL1 and the adjacent source-side select gate line SGS-USEL1 are charged to a negative voltage VOFF1 lower than 0 V. The voltage VOFF1 is generated by the negative voltage generating circuit 150 of the driver module 15.

Furthermore, at time t2, the memory device 1 starts applying a voltage VOFF2 of 0 V to the unselected drain-side select gate line SGD-USEL2 that is different from the adjacent drain-side select gate line SGD-USEL1. The memory device 1 starts applying a voltage VOFF2 of 0 V to the unselected source-side select gate line SGS-USEL2 that is different from the adjacent source-side select gate line SGS-USEL1.

### Time t3

At time t3, the voltage of the adjacent drain-side select gate line SGD-USEL1 and the voltage of the adjacent source-side select gate line SGS-USEL1 reach the negative voltage VOFF1. For example, the voltage value of the voltage VOFF1 is −2 V.

Thus, in the memory device 1 of the present embodiment, the select transistor ST1 connected to the adjacent drain-side select gate line SGD-USEL1 and the select transistor ST2 connected to the adjacent source-side select gate line SGS-USEL1 are turned off without being affected by the electric field EF generated from the selected drain-side select gate line SGD-SEL and the selected source-side select gate line SGS-SEL.

Furthermore, the voltage of the unselected drain-side select gate line SGD-USEL2 and the voltage of the unselected source-side select gate line SGS-USEL2 reach the voltage VOFF2. Thus, the select transistor ST1 connected to the adjacent drain-side select gate line SGD-USEL2 and the select transistor ST2 connected to the adjacent source-side select gate line SGS-USEL2 are cut off.

During the period from time t2 to time t3, in response to the select transistors ST1 and ST2 being in the off state, the semiconductor layer (channel) CHN-USEL of the memory pillar MP connected to the unselected select gate lines SGD-USEL1, SGS-USEL1, SGD-USEL2, and SGS-USEL2 rises in response to the charging voltage ΔV of the non-selected word line WL-USEL. For example, the voltage of the semiconductor layer CHN-USEL reaches the voltage VBoost.

In response to an increase in the voltage of the select transistors ST1 and ST2 in the off state and the semiconductor layer CHN-USEL, the magnitude of the charging current IWL decreases from the peak value i1.

After time t3, the voltages of the word lines WL-SEL and WL-USEL reach the voltage VREAD. The voltage of the selected drain-side select gate line SGD-SEL and the voltage of the selected source-side select gate line SGS-SEL reach the voltage VON. The select transistor ST1 connected to the selected drain-side select gate line SGD-SEL and the select transistor ST2 connected to the selected source-side select gate line SGS-SEL are turned on. This charges the capacitor between the word line and the memory pillar in the selected string unit SU.

### Time t4

After the voltages of the word lines WL-SEL and WL-USEL reach the voltage VREAD, at time t4, the memory device 1 applies a read voltage VCGRV to the selected word line WL-SEL. The memory device 1 applies a voltage VBL to the bit line BL and a voltage VCELSRC to the source line SL.

For example, in the memory pillar MP connected to the selected select gate lines SGD-SEL, SGS-SEL, the voltage of the semiconductor layer (channel) CHN-SEL rises to about the voltage VCELSRC.

By applying the non-selection voltage VREAD, the memory cells MC connected to the non-selected word line WL-USEL are turned on, regardless of the data stored in the memory cells MC.

By applying the read voltage VCGRV, the memory cell MC connected to the selected word line WL-SEL is turned on or off depending on the magnitude relationship between the threshold voltage of the memory cell MC corresponding to the data to be stored and the voltage value (read level) of the read voltage VCGRV.

When the read operation is a read of the lower page, the read voltage VCGRV includes two read levels VER and VAR. For example, the memory device 1 applies a voltage value corresponding to the read level VER to the selected word line WL-SEL. After applying the read level VER, the memory device 1 applies, to the selected word line WL-SEL, a voltage value corresponding to the read level VAR, which is lower than the read level ER. For example, when the read level VAR is a negative voltage value, the voltage of the selected word line WL-SEL becomes lower than 0 V. However, when a negative voltage is applied to the selected word line WL-SEL, the voltage value of the negative voltage applied to the selected word line WL-SEL is different from the voltage value of the negative voltage VOFF1.

When the page to be read is the upper page, the read voltage VCGRV includes the read level VCR and the read level VGR. Furthermore, when the page to be read is the middle page, the read voltage VCGRV includes a read level VBR, a read level VDR, and a read level VFR.

### Time t8

At time t8, the memory device 1 stops the application of the read voltage VCGRV to the selected word line WL-SEL, the application of the voltage VBL to the bit line BL, and the application of the voltage VCELSRC to the source line SL.

The memory device 1 starts applying the non-selection voltage VREAD to the selected word line WL-SEL. This causes the voltage of the selected word line WL-SEL to rise to the non-selection voltage VREAD. The memory cells MC connected to the selected word line WL are turned on by the non-selection voltage VREAD.

The memory device 1 stops application of the voltage VOFF1 to the adjacent drain-side select gate line SGD-USEL1 and the adjacent source-side select gate line SGS-USEL1, and stops application of the voltage VOFF2 to the unselected drain-side select gate line SGD-USEL2 and the unselected source-side select gate line SGS-USEL2.

The memory device 1 starts application of a positive voltage (for example, voltage VON) to the adjacent drain-side select gate line SGD-USEL1, the adjacent source-side select gate line SGS-USEL1, the unselected drain-side select gate line SGD-USEL2, and the unselected source-side select gate line SGS-USEL2. Thus, the voltages of the unselected drain-side select gate lines SGD-USEL1 and SGD-USEL2 and the unselected source-side select gate lines SGS-USEL1 and SGS-USEL2 rise to a positive voltage. The select transistor ST1 connected to the unselected drain-side select gate lines SGD-USEL1 and SGD-USEL2, and the select transistor ST2 connected to the unselected source-side select gate lines SGS-USEL1 and SGS-USEL2 are turned on by the applied positive voltage.

The memory pillars MP connected to the unselected select gate lines SGD-USEL1, SGD-USEL2, SGS-USEL1, and SGS-USEL2 are temporarily conductive to the bit lines BL and source lines SL via the select transistors ST1 and ST2 that are in the on state. Thus, the carriers (electrons/holes) trapped in the memory pillar MP are discharged.

### Time t9

At time t9, the memory device 1 stops applying voltages to the word lines WL-SEL and WL-USEL, the drain-side select gate lines SGD-SEL, SGD-USEL1, and SGD-USEL2, and the source-side select gate lines SGS-SEL, SGS-USEL1, and SGS-USEL2. Thus, the voltages of the word lines WL-SEL and WL-USEL, the voltages of the drain-side select gate lines SGD-SEL, SGD-USEL1, and SGD-USEL2, and the voltages of the source-side select gate lines SGS-SEL, SGS-USEL1, and SGS-USEL2 are set to 0 V.

The memory device 1 transfers the data output from the memory cell array 10 to the memory controller 2 as read data.

Through the above operations, the memory device 1 of the present embodiment completes the read operation.

The example of the operation of the memory device 1 of the present embodiment may be applied to a verification operation of a write operation of the memory device 1. The verification operation is different from the example of the read operation in FIG. 12 in that a verification voltage is applied to the selected word line WL-SEL. The verification voltage includes one or more verification levels. During the verification operation, the memory device 1 of the present embodiment applies a negative voltage VOFF1 to the adjacent drain-side/source-side select gate lines SGD-USEL1 and SGS-USEL1. This makes it possible to prevent the electric field from the selected drain-side/source-side select gate lines SGD-SEL and SGS-SEL from adversely affecting the off state of the select transistors ST1 and ST2 of the adjacent drain-side/source-side select gate lines SGD-USEL1 and SGS-USEL1 during the verification operation of the write operation.

Furthermore, the operation of the memory device 1 of the present embodiment may be applied to a verification operation of an erasing operation.

### (c) Summary

During operation of the memory device, large charging currents are generated in response to the charging of the word lines. The current required to charge the capacitor between the word line and the memory pillar increases as the word line becomes more multi-layered.

It is desirable to reduce the charging current of the word line without slowing down the charging speed of the word line in order to improve the performance of the memory device.

By electrically isolating the memory pillars of unselected string units from the bit lines and word lines during operation of the memory device, the effect of capacitor between the word lines and the memory pillars is reduced.

Various techniques were proposed to control the operation of the unselected string units independently of the operation of the selected string unit. For example, a plurality of physically separated select gate lines are provided in each block of the memory cell array. In order to prevent an increase in the manufacturing cost of the memory device, the interval between adjacent select gate lines is made relatively small.

During operation of the memory device, there is a possibility that an electric field from a selected drain-side/source-side select gate line weakly turns on a select transistor of an unselected drain-side/source-side select gate line adjacent to the selected drain-side/source-side select gate line. The select transistor in the weak on state causes leakage current to occur in the memory pillars corresponding to the unselected drain-side/source-side select gate lines. The occurrence of leakage causes the effect of the capacitor (for example, charging of capacitor) between the memory pillar MP and the wiring layer (word line) 22 to occur in the operation of the memory device 1. This causes the memory pillars corresponding to the unselected drain-side/source-side select gate lines to not be fully boosted.

In the memory device 1 of the present embodiment, during operation of the memory device, a voltage having a negative voltage value is applied to the unselected drain-side/source-side select gate lines (adjacent drain-side/source-side select gate lines) SGD-USEL1 and SGS-USEL1 adjacent to the selected drain-side/source-side select gate lines SGD-SEL and SGS-SEL.

Thus, in the memory device 1 of the present embodiment, even when an electric field EF from the selected drain-side/source-side select gate lines SGD-SEL and SGS-SEL is applied to the adjacent drain-side/source-side select gate lines, the select transistors ST1 and ST2 connected to the adjacent drain-side/source-side select gate lines SGD-USEL1 and SGS-USEL1 are turned off.

Therefore, in the memory device 1 of the present embodiment, the leakage that occurs in the memory pillars MP of the unselected string units SU can be reduced. As a result, in the memory device 1 of the present embodiment, the capacitor between the word line and the memory pillar in the unselected string units SU is not charged, and only the capacitor between the word line and the memory pillar in the selected string unit SU may be charged.

Therefore, in the memory device 1 of the present embodiment, the charging current of the word lines WL can be reduced.

In FIG. 12, the current waveform of the charging current IWL indicated by the dashed line indicates the current waveform when the select transistors ST1 and ST2 connected to the adjacent select gate lines SGD-USEL1 and SGS-USEL1 are in a weak on state due to the electric field generated from the selected select gate lines SGD-SEL and SGS-SEL. When the select transistors ST1 and ST2 connected to the adjacent select gate lines SGD-USEL1 and SGS-USEL1 are in a weak on state, a charging current having a current peak value i0 is generated due to the occurrence of leakage.

As in the present embodiment, the negative voltage VOFF1 is applied to the adjacent select gate lines SGD-USEL1 and SGS-USEL1, so that the electric fields generated from the selected select gate lines SGD-SEL and SGS-SEL are substantially cancelled out. Thus, the select transistors ST1 and ST2 connected to the adjacent select gate lines SGD-USEL1 and SGS-USEL1 are completely cut off. Therefore, the occurrence of leakage in the memory pillar MP connected to the adjacent select gate lines SGD-USEL1 and SGS-USEL1 is reduced. Therefore, the effect of the capacitor between the memory pillar MP and the word line WL connected to the adjacent select gate lines SGD-USEL1 and SGS-USEL1 is reduced.

As a result, in the present embodiment, the charging current IWL has a current peak value i1 that is lower than the current peak value i0. For example, the current peak value i1 is about one-fourth of the current peak value i0.

In this manner, in the memory device 1 of the present embodiment, the charging current IWL can be reduced.

In the memory device 1 of the present embodiment, the charging speed of the word lines WL can be increased in response to a reduction in the charging current IWL.

As described above, in the memory device 1 of the present embodiment, the operating characteristics of the memory device can be improved.

### (2) Second Embodiment

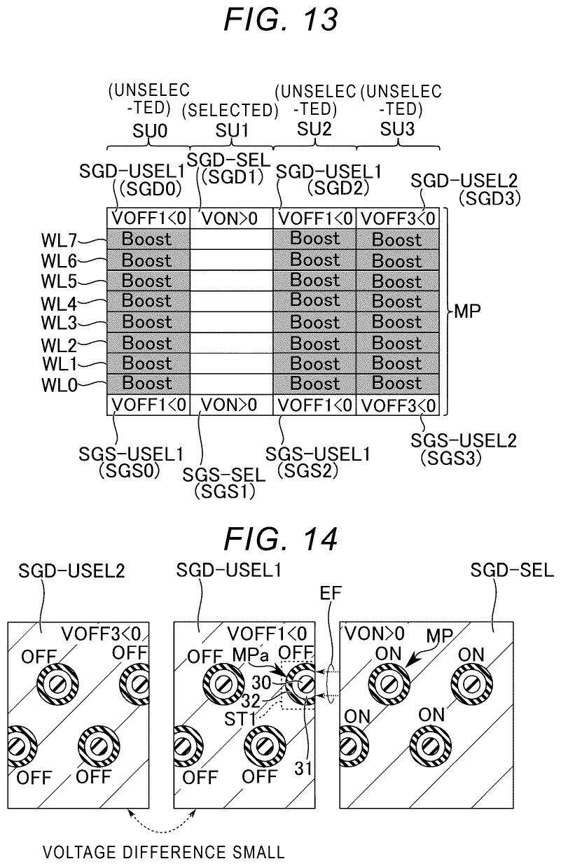

A memory device and a method for controlling the memory device according to a second embodiment will be described with reference to FIGS. 13 to 15.

FIGS. 13 and 14 are schematic diagrams illustrating an outline of the operation of the memory device 1 of the present embodiment.

As shown in FIG. 13, the memory device 1 of the present embodiment applies a negative voltage VOFF3 to the adjacent drain-side/source-side select gate lines SGD-USEL1 and SGS-USEL1, as well as to the unselected drain-side/source-side select gate lines SGD-USEL2 and SGS-USEL2 that are not adjacent to the selected drain-side/source-side select gate lines SGD-SEL and SGS-SEL.

The voltage VOFF3 is, for example, lower than 0 V and higher than the voltage VOFF1. For example, the voltage VOFF3 has a voltage value within the range of −1.7 V to −1 V. The voltage value of the voltage VOFF3 may be the same as the voltage value of the voltage VOFF1 as long as the voltage value is smaller than 0 V.

As shown in FIG. 14, a negative voltage VOFF3 is applied to the unselected drain-side select gate line SGD-USEL2 adjacent to the adjacent drain-side select gate line SGD-USEL1, thereby reducing the voltage difference between the unselected drain-side select gate line SGD-USEL2 and the adjacent drain-side select gate line SGD-USEL1.

Thus, interference caused by the voltage difference between the unselected drain-side select gate line SGD-USEL2 and the adjacent drain-side select gate line SGD-USEL1 is reduced.

Similarly, application of a negative voltage VOFF3 to the unselected source-side select gate line SGS-USEL2 reduces interference caused by the voltage difference between the unselected source-side select gate line SGS-USEL2 and the adjacent source-side select gate line SGS-USEL1.

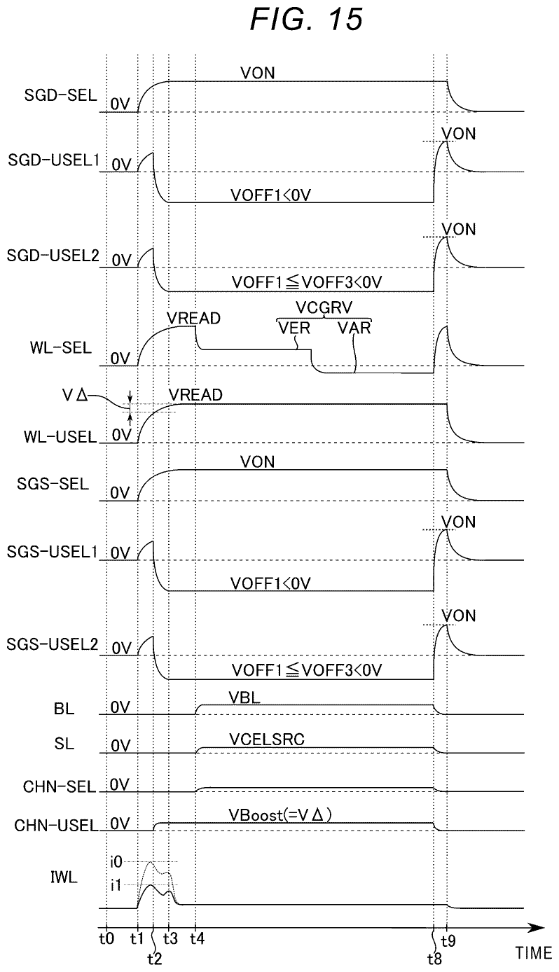

FIG. 15 is a timing chart showing an example of the operation of the memory device 1 of the present embodiment.

As shown in FIG. 15, at time t1, the memory device 1 applies a positive voltage (for example, voltage VON) to the drain-side select gate lines SGD-SEL, SGD-USEL1, and SGD-USEL2 and the source-side select gate lines SGS-SEL, SGS-USEL1, and SGS-USEL2.

At time t2, the memory device 1 applies a negative voltage VOFF1 to the adjacent drain-side select gate line SGD-USEL1 and the adjacent source-side select gate line SGS-USEL1. At this time, the memory device 1 applies the voltage VOFF1 to the adjacent drain-side/source-side select gate lines SGD-USEL1 and SGS-USEL1, and also applies the negative voltage VOFF3 to the unselected drain-side select gate line SGD-USEL2 and the unselected source-side select gate line SGS-USEL2.

At time t3, the voltages of the unselected drain-side select gate line SGD-USEL2 and the unselected source-side select gate line SGS-USEL2 reach the negative voltage VOFF3.

At time t4, the memory device 1 applies a read voltage VCGRV to the selected word line WL-SEL.

At time t8, the memory device 1 applies the voltage VON to the adjacent drain-side/source-side select gate lines SGD-USEL1 and SGS-USEL1, and also applies the voltage VON to the unselected drain-side select gate line SGD-USEL2 and the unselected source-side select gate line SGS-USEL2.

At time t9, the memory device 1 stops applying voltages to the word lines WL-SEL and WL-USEL, the drain-side select gate lines SGD-SEL, SGD-USEL1, and SGD-USEL2, and the source-side select gate lines SGS-SEL, SGS-USEL1, and SGS-USEL2.

As described above, the memory device 1 of the present embodiment completes the read operation.

As described above, by applying a negative voltage VOFF3 to the unselected drain-side select gate line SGD-USEL2 and the unselected source-side select gate line SGS-USEL2, the influence of the voltage difference between the unselected drain-side select gate line SGD-USEL2 and the adjacent drain-side select gate line SGD-USEL1, and the influence of the voltage difference between the unselected source-side select gate line SGS-USEL2 and the adjacent source-side select gate line SGS-USEL1 can be reduced.

Therefore, in the memory device 1 of the present embodiment, the reliability of the operation of the memory device 1 can be improved.

As a result, in the memory device 1 of the present embodiment, the operating characteristics of the memory device can be improved.

### (3) Third Embodiment

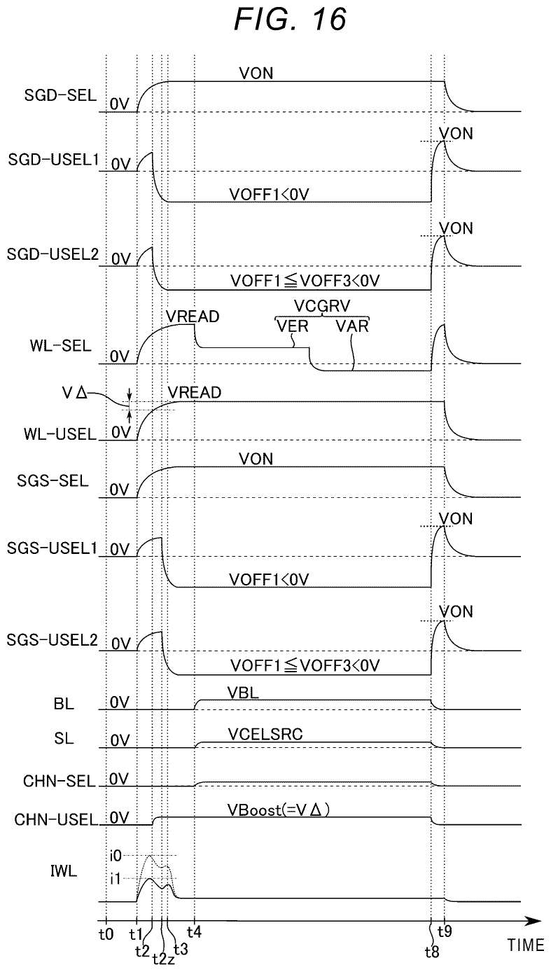

A memory device and a method for controlling the memory device according to a third embodiment will be described with reference to FIG. 16.

FIG. 16 is a timing chart showing an example of the operation of the memory device 1 of the present embodiment.

As shown in FIG. 16, the timing (time) of application of the negative voltage VOFF1 to the adjacent drain-side select gate line SGD-USEL1 differs from the timing of application of the negative voltage VOFF1 to the adjacent source-side select gate line SGS-USEL1. Furthermore, the timing of application of the negative voltage VOFF3 to the unselected drain-side select gate line SGD-USEL2 differs from the timing of application of the negative voltage VOFF3 to the unselected source-side select gate line SGS-USEL2.

For example, at time t2, the memory device 1 applies a negative voltage VOFF1 to the adjacent drain-side select gate line SGD-USEL1 and applies a negative voltage VOFF3 to the unselected drain-side select gate line SGD-USEL2. At this time, a positive voltage VON is applied to the adjacent source-side select gate line SGS-USEL1 and the unselected source-side select gate line SGS-USEL2.

At time t2z after time t2, the memory device 1 applies a negative voltage VOFF1 to the adjacent source-side select gate line SGS-USEL1 and applies a negative voltage VOFF3 to the unselected source-side select gate line SGS-USEL2. For example, the voltage of the adjacent source-side select gate line SGS-USEL1 and the voltage of the unselected source-side select gate line SGS-USEL2 reach the desired value after time t3.

At time t4, the memory device 1 applies a read voltage VCGRV to the selected word line WL-SEL.

At time t8, the memory device 1 applies a positive voltage VON to the adjacent drain-side/source-side select gate lines SGD-USEL1 and SGS-USEL1 and the unselected drain-side/source-side select gate lines SGD-USEL2 and SGS-USEL2.

At time t9, the memory device 1 applies a voltage of 0 V to the adjacent drain-side/source-side select gate lines SGD-USEL1 and SGS-USEL1 and the unselected drain-side/source-side select gate lines SGD-USEL2 and SGS-USEL2.

As described above, the memory device 1 of the present embodiment completes the read operation.

After the negative voltages VOFF1 and VOFF3 are applied to the adjacent/unselected source-side select gate lines SGS-USEL1, SGS-USEL2, the negative voltages VOFF1 and VOFF3 may be applied to the adjacent/unselected drain-side select gate lines SGD-USEL1, SGD-USEL2.

The voltage applied to the unselected drain-side select gate line SGD-USEL2 and the unselected source-side select gate line SGS-USEL2 may be a voltage VOFF2 of 0 V.

The timing at which the application of the voltages VOFF1 and VOFF3 to the adjacent/unselected source-side select gate lines SGS-USEL1 and SGS-USEL2 is stopped may be different from the timing at which the application of the voltages VOFF1 and VOFF3 to the adjacent/unselected drain-side select gate lines SGD-USEL1 and SGD-USEL2 is stopped.

In the present embodiment, the timing of voltage application to the adjacent/unselected source-side select gate lines SGS-USEL1, SGS-USEL2 is different from the timing of voltage application to the adjacent/unselected drain-side select gate lines SGD-USEL1 and SGD-USEL2, thereby adjusting the stability of operation of the memory device 1.

As a result, in the memory device 1 of the present embodiment, the reliability of the operation of the memory device can be improved.

Therefore, in the memory device 1 of the present embodiment, the operating characteristics of the memory device can be improved.

### (4) Fourth Embodiment

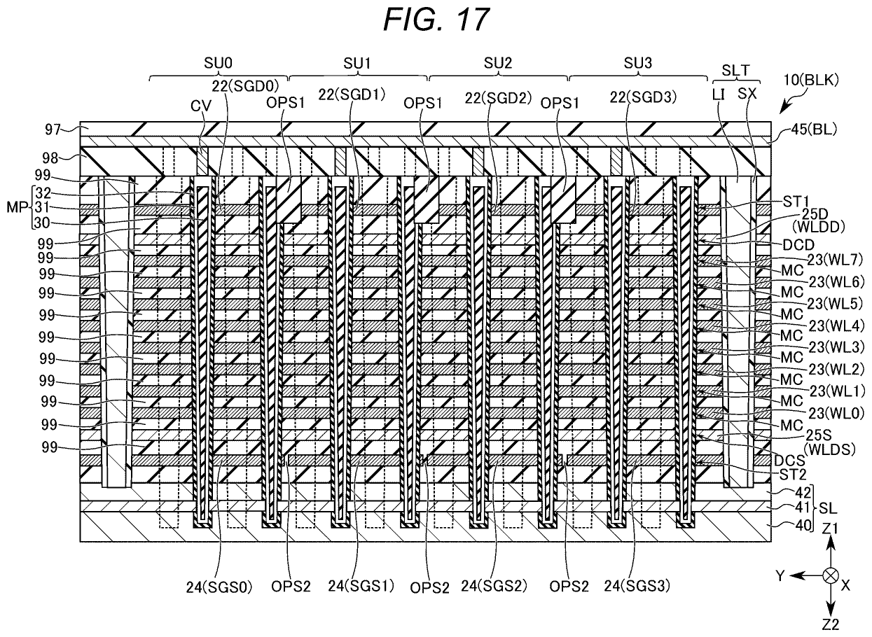

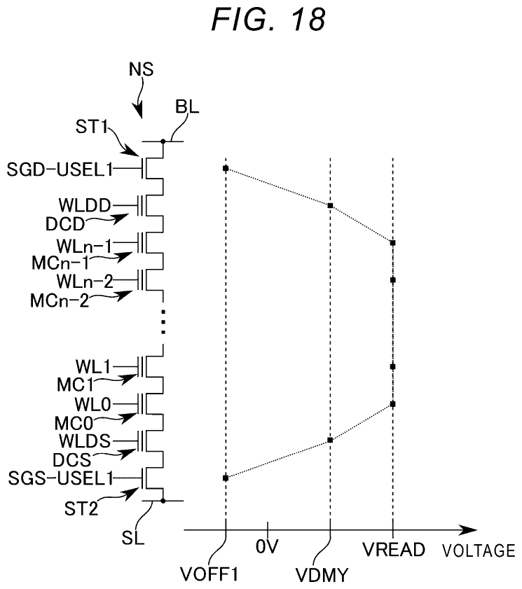

The memory device of a fourth embodiment and an example of the operation of the memory device will be described with reference to FIGS. 17 and 18.

FIG. 17 is a cross-sectional view showing a structure example of the memory device 1 of the present embodiment.

As shown in FIG. 17, the memory device 1 of the present embodiment includes dummy word lines WLDD and WLDS in the memory cell array 10.

The wiring layer 25D as the dummy word line WLDD is provided between the drain-side select gate line layer 22 and the uppermost word line layer 23 (WL7). The wiring layer 25S as the dummy word line WLDS is provided between the source-side select gate line layer 24 and the lowest word line layer 23 (WL0). Each of the wiring layers 25D and 25S extends in the X direction.

The memory pillar MP penetrates the wiring layers 25D and 25S.

The portion where the memory pillar MP and the wiring layer 25D intersect functions as a memory cell (dummy cell) DCD that is not used to store data such as information from the user and setting information. The portion where the memory pillar MP and the wiring layer 25S intersect functions as a dummy cell DCS.

FIG. 18 is a diagram showing the circuit configuration of a NAND string NS including dummy word lines WLDD and WLDS in the memory device 1 of the present embodiment, and the voltages applied to each wiring during the operation of the memory device 1.

As shown in FIG. 18, the dummy cell DCD is connected between the select transistor ST1 and the memory cell MC7, and the dummy cell DCS is connected between the select transistor ST2 and the memory cell MC1.

The gate of the dummy cell DCD on the drain side of the NAND string NS is connected to the dummy word line WLDD. The gate of the dummy cell DCS on the source side of the NAND string NS is connected to the dummy word line WLDS. The dummy word lines WLDD and WLDS are word lines to which the dummy cells DCD and DCS are connected, and are word lines not accessed by the user.

At a certain time during a read operation of the memory device 1, as described above, the memory device 1 applies a negative voltage VOFF1 to the adjacent drain-side/source-side select gate lines SGD-USEL1 and SGS-USEL1. The memory device 1 applies a non-selection voltage VREAD to the word line WL.

In the present embodiment, the memory device 1 applies a voltage VDMY to the dummy word lines WLDD and WLDS. The voltage VDMY has a voltage value between the non-selection voltage VREAD and the voltage VOFF1. For example, the voltage VDMY is a positive voltage. The voltage VDMY has a voltage value of about +2 V to +4 V.

By applying a voltage to the dummy word lines WLDD and WLDS, the gradient (amount of change) of the voltage between the select gate line SG (SGD, SGS) and the word line WL becomes gentle.

Thus, in the memory device 1 of the present embodiment, deterioration of reliability due to a high electric field generated between the select gate line SG and the word line WL can be reduced.

As described above, in the memory device 1 of the present embodiment, the operating characteristics of the memory device can be improved.

### (5) Fifth Embodiment

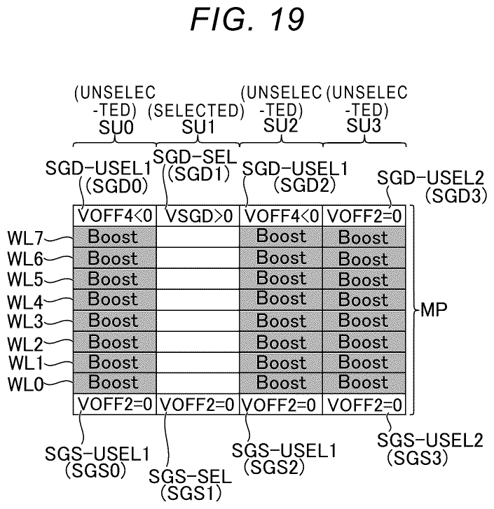

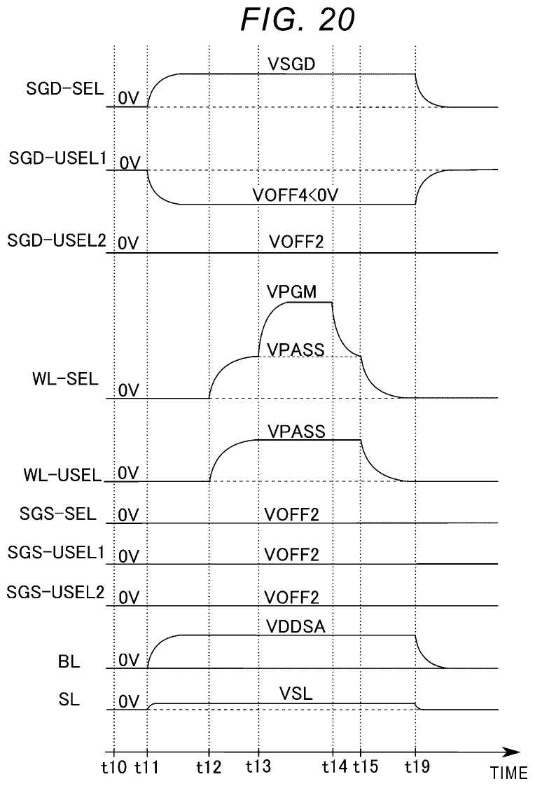

A memory device and a method for controlling the memory device according to a fifth embodiment will be described with reference to FIGS. 19 and 20.

FIG. 19 is a schematic diagram illustrating the operating state of the memory device 1 of the present embodiment during a write operation.

As shown in FIG. 19, during a program operation of the write operation, the memory device 1 of the present embodiment applies a program voltage VPGM or a non-selection voltage VPASS to the word line WL.

The memory device 1 applies a voltage VSGD having a positive voltage value to a selected drain-side select gate line SGD-SEL (for example, the select gate line SGD1). The voltage value of the voltage VSGD is, for example, +2 V. The memory device 1 applies a voltage VOFF2 having a voltage value of 0 V to an unselected drain-side select gate line (for example, select gate line SGD3) SGD-USEL2.

During a program operation, the memory device 1 applies a voltage VOFF2 (VSGS) having a voltage value of 0 V to the source-side select gate lines SGS-SEL, SGS-USEL1, and SGS-USEL2.

In the present embodiment, the memory device 1 applies a voltage VOFF4 having a negative voltage value to the adjacent drain-side select gate line SGD-USEL1 (for example, select gate lines SGD0 and SGD2). The voltage value of the voltage VOFF4 is within the range of −2 V to −1 V.

Thus, during the program operation, leakage from the memory pillar MP connected to the adjacent drain-side select gate line SGD-USEL1 is reduced.

FIG. 20 is a timing chart showing an example of the operation of the memory device 1 of the present embodiment.

Time t10

As shown in FIG. 20, at time t10, the memory device 1 starts a write operation on the operation target indicated by the address ADD based on the command CMD from the memory controller 2.

### Time t11

In the j-th (j is an integer equal to or greater than 1) write loop of the write operation, at time t11, the memory device 1 starts applying voltages to the bit line BL, the source line SL, and the select gate lines SGD and SGS.

The memory device 1 applies a voltage of 0 V to the bit line BL to which the memory cell MC to be programmed is connected. The memory device 1 applies a voltage VDDSA having a positive voltage value to the bit line BL to which the memory cell MC that is not to be programmed is connected.

The memory device 1 applies a voltage VSL having a positive voltage value to the source line SL.

The memory device 1 applies a voltage VOFF2 having a voltage value of 0 V to the selected source-side select gate line SGS-SEL, the adjacent source-side select gate line SGS-USEL1, and the unselected source-side select gate line SGS-USEL2.

The memory device 1 applies a voltage VSGD having a positive voltage value to the selected drain-side select gate line SGD-SEL corresponding to the selected string unit SU. The memory device 1 applies a voltage VOFF2 having a voltage value of 0 V to the unselected drain-side select gate line SGD-USEL2 that is not adjacent to the selected drain-side select gate line SGD-SEL.

In the present embodiment, the memory device 1 applies the voltage VOFF4 having a negative voltage value (for example, −2 V) to the adjacent drain-side select gate line SGD-USEL1.

The select transistor ST1 connected to the bit line BL to which the voltage VDDSA is applied and the unselected drain-side select gate lines SGD-USEL1 and SGD-USEL2 is cut off.

### Time t12

At time t12, the memory device 1 applies the non-selection voltage VPASS to the selected word line WL-SEL and the non-selected word lines WL-USEL. Thus, the semiconductor layer 31 of the memory pillar MP connected to the adjacent/unselected drain-side select gate lines SGD-USEL1 and SGD-USEL2 is boosted.

In the present embodiment, the negative voltage VOFF4 is applied to the adjacent drain-side select gate line SGD-USEL1, thereby reducing leakage that occurs in the memory pillar MP connected to the adjacent drain-side select gate line SGD-USEL1. Therefore, the channel boost failure in the semiconductor layer 31 during the program operation is reduced.

### Time t13

At time t13, the memory device 1 applies a program voltage VPGM higher than the non-selection voltage VPASS to the selected word line WL-SEL. The voltage of the selected word line WL-SEL rises from the non-selection voltage VPASS to the program voltage VPGM.

Application of the program voltage VPGM increases the threshold voltage of the memory cell MC to be programmed.

### Time t14

At time t14, the memory device 1 stops applying the program voltage VPGM. The memory device 1 applies a non-selection voltage VPASS to the selected word line WL-SEL. The voltage of the selected word line WL-SEL drops from the program voltage VPGM to the non-selection voltage VPASS.

### Time t15

At time t15, the memory device 1 stops applying voltage to the selected word line WL-SEL and the non-selected word line WL-USEL. The voltage of the selected word line WL-SEL and the voltage of the non-selected word line WL-USEL become 0 V.

### Time t19

At time t19, the memory device 1 stops applying voltages to the bit line BL, the source line SL, and the select gate lines SGD and SGS. The voltages of the bit line BL and the source line become 0 V. The voltage of the selected source-side select gate line SGS-SEL and the voltages of the adjacent/unselected source-side select gate lines SGS-USEL1 and SGS-USEL2 become 0 V. The voltage of the selected drain-side select gate line SGD-SEL drops from the voltage VSGD to 0 V. The voltage of the unselected drain-side select gate line SGD-USEL2 becomes 0 V. The voltage of the adjacent drain-side select gate line SGD-USEL1 rises from the voltage VOFF4 to 0 V.

Thus, the memory device 1 completes the program operation.

After the program operation, the memory device 1 performs a verification operation. As described above, during the verification operation, the memory device 1 applies the negative voltage VOFF1 to the adjacent drain-side/source-side select gate lines SGD-USEL1 and SGS-USEL1. During the verification operation, the memory device 1 may apply the negative voltage VOFF3 to the unselected drain-side/source-side select gate lines SGD-USEL2 and SGS-USEL2.

When the result of the verification operation is a fail, the memory device 1 executes the program operation again. When the result of the verification operation is a pass, the memory device completes the write operation.

In this manner, the memory device 1 completes the write operation.

During the program operation, the negative voltage VOFF4 may be applied to the adjacent source-side select gate line SGS-USEL1. The negative voltage VOFF4 may be applied to the unselected drain-side select gate line SGD-USEL2 and the unselected source-side select gate line SGS-USEL2. During the program operation, the negative voltage VOFF4 may be applied to the selected source-side select gate line SGS-SEL.

The memory device 1 of the present embodiment can prevent the select transistor ST1 connected to the adjacent select gate line SGD-USEL1 from being in a weak on state due to the influence of the electric field from the selected select gate line SGD-SEL during the program operation.

Therefore, during the program operation, the memory device 1 of the present embodiment can boost the voltage of the semiconductor layer of the memory pillar MP connected to the adjacent select gate line SGD-USEL1 without being affected by leakage caused by the select transistor ST1 in a weak on state.

As a result, the memory device 1 of the present embodiment can reduce erroneous writing during a write operation and improve the charging speed of the wiring.

As described above, in the memory device 1 of the present embodiment, the operating characteristics of the memory device can be improved.

### (6) Sixth Embodiment

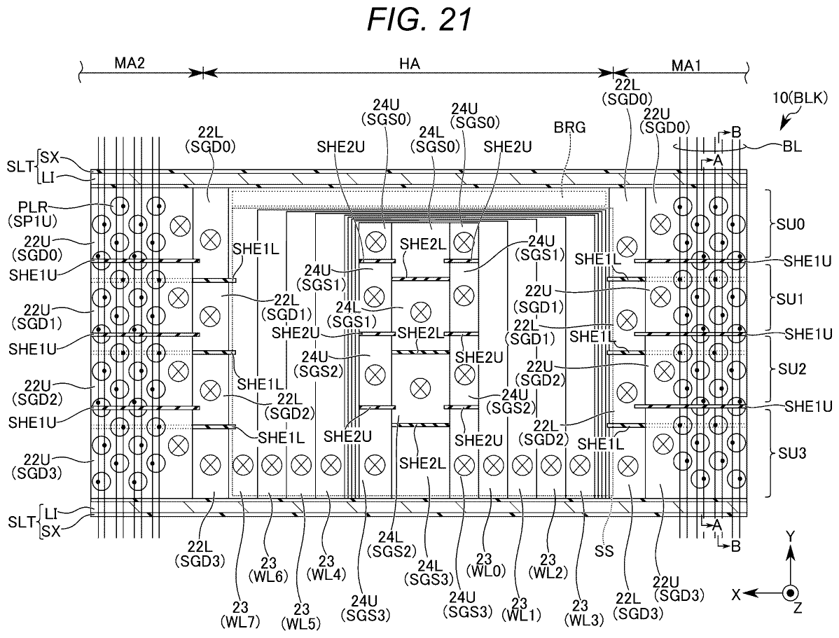

A memory device according to a sixth embodiment and an example of the operation of the memory device will be described with reference to FIGS. 21 to 27.

### (a) Configuration Example

A configuration example of the memory device 1 of the present embodiment will be described with reference to FIGS. 21 to 26.

### (a-1) Memory Cell Array Structure

The structure of the memory device 1 of the present embodiment will be described with reference to FIGS. 21 to 25.

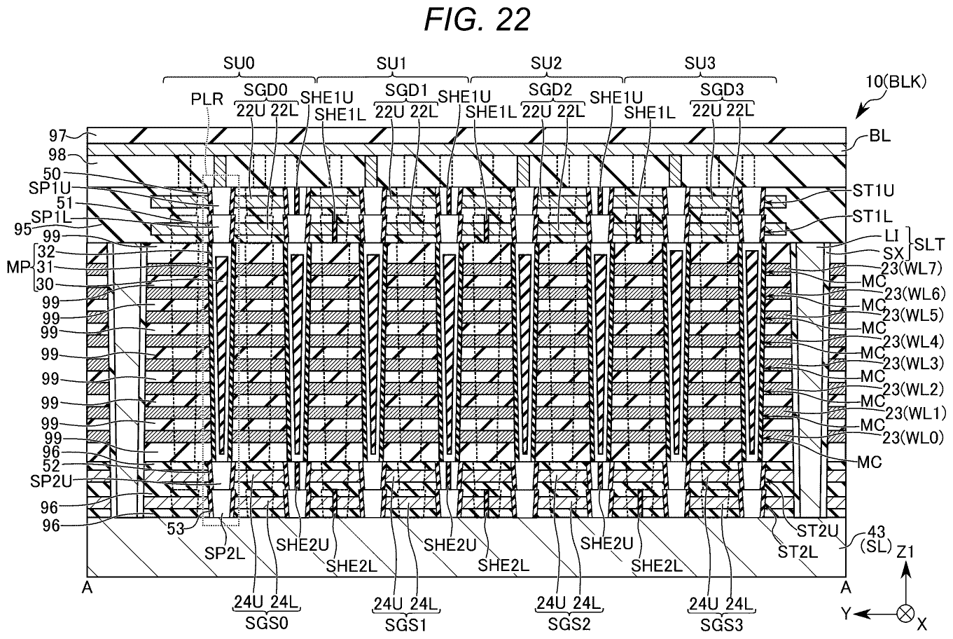

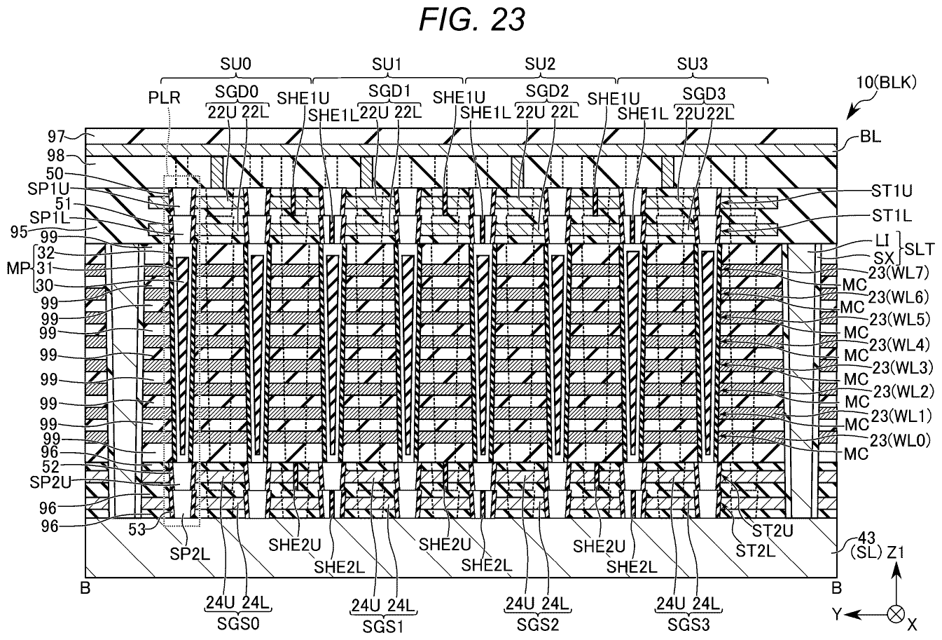

FIG. 21 is a plan view showing a structure example of the memory device 1 of the present embodiment. FIGS. 22 and 23 are cross-sectional views showing structure examples of the memory device 1 of the present embodiment. FIG. 22 shows a cross-sectional structure of the memory cell array 10 taken along line A-A in FIG. 21. FIG. 23 shows a cross-sectional structure of the memory cell array 10 taken along line B-B in FIG. 21.

As shown in FIGS. 21 to 23, the memory device 1 of the present embodiment differs from the memory device 1 of the other embodiments described above in the configurations of the select gate lines SGD and SGS and the select transistors ST1 (ST1U, ST1L) and ST2 (ST2U, ST2L).

Each of the plurality of drain-side select gate lines SGD (SGD0, SGD1, SGD2, SGD3) includes two wiring layers 22U and 22L. Each of the plurality of source-side select gate lines SGS (SGS0, SGS1, SGS2, SGS3) includes two wiring layers 24U, 24L.

The wiring layers 22U and 22L are provided above a set of stacked wiring layers 23 (word lines WL) in the Z direction. The plurality of wiring layers 22U are provided above the plurality of wiring layers 22L and below the bit lines BL in the Z direction. The plurality of wiring layers 22U are aligned in the Y direction. The plurality of wiring layers 22L are aligned in the Y direction. A set of two wiring layers 22U, 22L overlapping in the Z direction corresponds to one drain-side select gate line SGD. In one block BLK, when the number of string units SU is four, the number of wiring layers 22U aligned in the Y direction in each memory area MA1 and MA2 is four and the number of wiring layers 22L aligned in the Y direction is four. The wiring layers 22U and 22L are covered with an insulating layer 95.

In a pair of wiring layers 22U, 22L (wiring layers 22U, 22L forming one drain-side select gate line SGD) overlapping in the Z direction, the dimension of the wiring layer 22U in the Y direction is different from the dimension of the wiring layer 22L in the Y direction. In one pair of wiring layers 22U, 22L, the contacts CC on the wiring layer 22U are aligned with the contacts CC on the wiring layer 22L in a direction oblique to the X and Y directions.

The wiring layers 24U and 24L are provided below a set of stacked wiring layers 23 (word lines WL) in the Z direction. The plurality of wiring layers 24U are provided above the plurality of wiring layers 24L and below the word lines WL in the Z direction. The plurality of wiring layers 24U are aligned in the Y direction. The plurality of wiring layers 24L are aligned in the Y direction. A set of two wiring layers 24U, 24L overlapping in the Z direction corresponds to one source-side select gate line SGS. In one block BLK, when the number of string units SU is four, the number of wiring layers 24U aligned in the Y direction in each memory area MA1, MA2 is four and the number of wiring layers 24L aligned in the Y direction is four. The wiring layers 22U and 22L are covered with an insulating layer 96.

In a pair of wiring layers 24U, 24L (wiring layers 24U, 24L forming one source-side select gate line SGS) overlapping in the Z direction, the dimension of the wiring layer 24U in the Y direction is different from the dimension of the wiring layer 24L in the Y direction. In one pair of wiring layers 24U, 24L, the contacts CC on the wiring layer 24U are aligned with the contacts CC on the wiring layer 24L in a direction oblique to the X and Y directions.

In the present embodiment, the pillar portion PLR includes semiconductor pillars SP1U, SP1L, SP2U, and SP2L in addition to the memory pillar MP.

The plurality of semiconductor pillars SP1U and SP1L are provided above the memory pillar MP in the Z direction. The semiconductor pillar SP1U is provided above the semiconductor pillar SP1L in the Z direction. The semiconductor pillar SP1L is provided between the semiconductor pillar SP1U and the memory pillar MP. The semiconductor pillar SP1L connects the semiconductor pillar SP1U to the memory pillar MP. The semiconductor pillar SP1U is connected to the bit line BL via a contact CV.

The plurality of semiconductor pillars SP1U penetrate each wiring layer 22U. An insulating layer (gate insulating film) 50 is provided between the side surface of the semiconductor pillar SP1U and the wiring layer 22U. The portion where the semiconductor pillar SP1U and the wiring layer 22U intersect functions as a select transistor ST1U.

The plurality of semiconductor pillars SP1L penetrate each wiring layer 22L. An insulating layer (gate insulating film) 51 is provided between the side surface of the semiconductor pillar SP1L and the wiring layer 22L. The portion where the semiconductor pillar SP1L and the wiring layer 22L intersect functions as a select transistor ST1L.

The plurality of semiconductor pillars SP2U and SP2L are provided below the memory pillar MP in the Z direction. The semiconductor pillar SP2U is provided above the semiconductor pillar SP2L in the Z direction. The semiconductor pillar SP2U is provided between the semiconductor pillar SP2L and the memory pillar MP. The semiconductor pillar SP2U connects the semiconductor pillar SP2L to the memory pillar MP. The semiconductor pillar SP2L is directly connected to the wiring layer 43 of the source line SL.

The plurality of semiconductor pillars SP2U penetrate each wiring layer 24U. An insulating layer (gate insulating film) 52 is provided between the side surface of the semiconductor pillar SP2U and the wiring layer 24U. The portion where the semiconductor pillar SP2U and the wiring layer 24U intersect functions as a select transistor ST2U.

The plurality of semiconductor pillars SP2L penetrate each wiring layer 24L. An insulating layer (gate insulating film) 53 is provided between the side surface of the semiconductor pillar SP2L and the wiring layer 24L. The portion where the semiconductor pillar SP2L and the wiring layer 24L intersect functions as a select transistor ST2L.

The member SHE1U is provided between the wiring layers 22U adjacent to each other in the Y direction. The member SHE1U separates adjacent wiring layers 22U. The member SHE1L is provided between the wiring layers 22L adjacent to each other in the Y direction. The member SHE1L separates adjacent wiring layers 22L. The member SHE1L does not overlap with the member SHE1U in the Z direction.

The member SHE2U is provided between the wiring layers 24U adjacent to each other in the Y direction. The member SHE2U separates adjacent wiring layers 24U. The member SHE2L is provided between the wiring layers 24L adjacent to each other in the Y direction. The member SHE2L separates adjacent wiring layers 24L. The member SHE2L does not overlap with the member SHE2U in the Z direction.

The memory device 1 of the present embodiment can be formed by a combination of well-known memory device manufacturing processes.

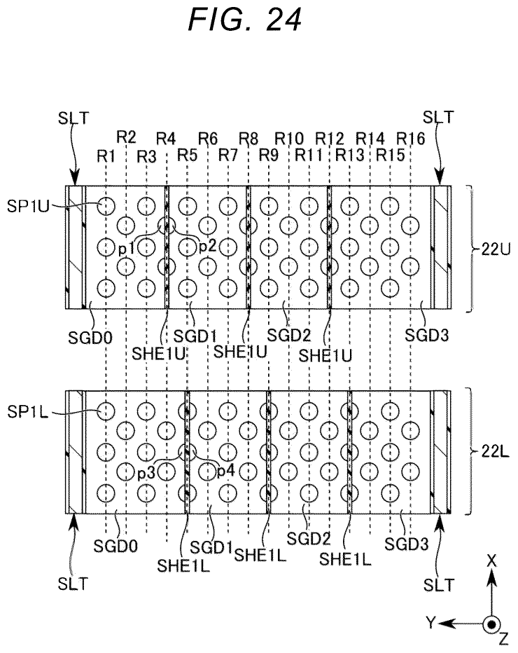

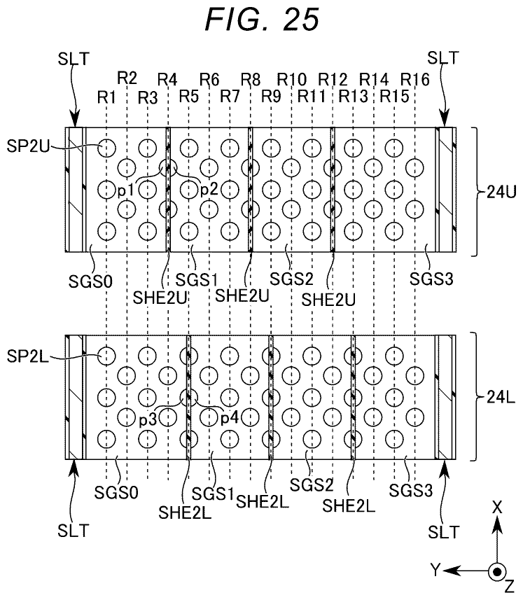

The configuration of the drain-side select gate line SGD and the source-side select gate line SGS in the memory device of the present embodiment will be described more specifically with reference to FIGS. 24 and 25.

FIG. 24 is a plan view schematically showing the structure of the wiring layers 22U and 22L in the hierarchy where the wiring layer 22U is provided and in the hierarchy where the wiring layer 22L is provided, with respect to the drain-side select gate line SGD. In FIG. 24, the insulating layers 50 and 51 are omitted. FIG. 25 is a plan view schematically showing the structure of the wiring layers 24U and 24L in the hierarchy where the wiring layer 24U is provided and in the hierarchy where the wiring layer 24L is provided, with respect to the source-side select gate line SGS. In addition, in FIG. 25, the insulating layers 52 and 53 are omitted.

As shown in FIG. 24, the plurality of semiconductor pillars SP1U and the plurality of semiconductor pillars SP1L are arranged in a staggered arrangement in each hierarchy (wiring level) so as to correspond to the arrangement of the memory pillars MP. Hereinafter, a set of plurality of semiconductor pillars SP1 and SP2 (pillar portions PLR) aligned on the same straight line in the X direction will be referred to as a pillar set. For example, one string unit SU includes four rows of pillar sets. In this case, the boundary between two string units SU is present between the pillar set in the 4k-th row and the pillar set in the (4k+1)-th row.

For example, in the semiconductor pillars SP1U and SP1L, a pillar set in 16 rows R1, R2, . . . , R15, R16 is provided between two members SLT aligned in the Y direction. The two members SLT are provided on one end side and the other end side of the block BLK in the Y direction, respectively.

With respect to the semiconductor pillars SP1U, in each wiring layer 22U, four pillar sets are aligned in the Y direction. With respect to the semiconductor pillars SP1L, in each wiring layer 22L, four pillar sets are aligned in the Y direction.

As shown in FIG. 25, the plurality of semiconductor pillars SP2U and the plurality of semiconductor pillars SP2L are arranged in a staggered arrangement in each hierarchy so as to correspond to the arrangement of the memory pillars MP.

For example, in the semiconductor pillars SP2U and SP2L, a pillar set in 16 rows R1, R2, . . . , R15, R16 is provided between two members SLT aligned in the Y direction.

With respect to the semiconductor pillars SP2U, in each wiring layer 24U, four pillar sets are aligned in the Y direction. With respect to the semiconductor pillars SP2L, in each wiring layer 24L, four pillar sets are aligned in the Y direction.

The members SHE1U, SHE2U, SHE1L, and SHE2L are provided on the semiconductor pillars SP1U, SP2U, SP1L, and SP2L of the pillar set in a certain row.

In the wiring layers 22U and 24U, the members SHE1U and SHE2U overlap with the semiconductor pillars SP1U and SP2U of the pillar sets in the fourth row R4, the eighth row R8, and the twelfth row R12. The members SHE1U and SHE2U extend in the X direction to overlap with the centers of the semiconductor pillars SP1U and SP2U. Each of the semiconductor pillars SP1U, SP2U in the pillar sets in the fourth row R4, the eighth row R8, and the twelfth row R12 includes two portions p1 and p2 split in the Y direction. The two portions p1 and p2 are independent of each other.

The two wiring layers 22U and the two wiring layers 24U adjacent to each other in the Y direction are electrically isolated by the members SHE1U and SHE2U. The wiring layer 22U between the member SLT on one end side and the member SHE1U on the pillar set in the fourth row R4 corresponds to the drain-side select gate line SGD0. The wiring layer 22U between the member SHE1U on the pillar set in the fourth row R4 and the member SHE1U on the pillar set in the eighth row R8 corresponds to the drain-side select gate line SGD1. The wiring layer 22U between the member SHE1U on the pillar set in the eighth row R8 and the member SHE1U on the pillar set in the twelfth row R12 corresponds to the drain-side select gate line SGD2. The wiring layer 22U between the member SHE1U on the pillar set in the twelfth row R12 and the member SLT on the other end side corresponds to the drain-side select gate line SGD3. The wiring layer 24U between the member SLT on one end side and the member SHE2U on the pillar set in the fourth row R4 corresponds to the source-side select gate line SGS0. The wiring layer 24U between the member SHE2U on the pillar set in the fourth row R4 and the member SHE2U on the pillar set in the eighth row R8 corresponds to the source-side select gate line SGS1. The wiring layer 24U between the member SHE2U on the pillar set in the eighth row R8 and the member SHE2U on the pillar set in the twelfth row R12 corresponds to the source-side select gate line SGS2. The wiring layer 24U between the member SHE2U on the pillar set in the twelfth row R12 and the member SLT on the other end side corresponds to the source-side select gate line SGS3.

In the wiring layers 22L and 24L, the members SHE1L and SHE2L overlap with the pillar sets SP1L and SP2L in the fifth row R5, the ninth row R9, and the thirteenth row R13. The members SHE1L and SHE2L extend in the X direction to overlap with the centers of the semiconductor pillars SP1L and SP2L. Each of the semiconductor pillars SP1L and SP2L in the pillar sets in the fifth row R5, the ninth row R9, and the thirteenth row R13 includes two portions p3 and p4 split in the Y direction. The two portions p3 and p4 are independent of each other.

The two wiring layers 22L and the two wiring layers 24L adjacent to each other in the Y direction are electrically isolated by the members SHE1L and SHE2L. The wiring layer 22L between the member SLT on one end side and the member SHE1L on the pillar set in the fifth row R5 corresponds to the drain-side select gate line SGD0. The wiring layer 22L between the member SHE1L on the pillar set in the fifth row R5 and the member SHE1L on the pillar set in the ninth row R9 corresponds to the drain-side select gate line SGD1. The wiring layer 22L between the member SHE1L on the pillar set in the ninth row R9 and the member SHE1L on the pillar set in the thirteenth row R13 corresponds to the drain-side select gate line SGD2. The wiring layer 22L between the member SHE1L on the pillar set in the 13th row R13 and the member SLT on the other end side corresponds to the drain-side select gate line SGD3. The wiring layer 24L between the member SLT on one end side and the member SHE2L on the pillar set in the fifth row R5 corresponds to the source-side select gate line SGS0. The wiring layer 24L between the member SHE2L on the pillar set in the fifth row R5 and the member SHE2L on the pillar set in the ninth row R9 corresponds to the source-side select gate line SGS1. The wiring layer 24L between the member SHE2U on the pillar set in the ninth row R9 and the member SHE2L on the pillar set in the thirteenth row R13 corresponds to the source-side select gate line SGS2. The wiring layer 24L between the member SHE2L on the pillar set in the 13th row R13 and the member SLT on the other end side corresponds to the source-side select gate line SGS3.

Thus, in the present embodiment, in the wiring layers 22U and 22L in each of the plurality of drain-side select gate lines SGD, the member SHE1U for separating adjacent upper wiring layers 22U is provided at a position overlapping with the semiconductor pillar SP1U in the 4k-th row, and the member SHE1L for separating adjacent lower wiring layers 22L is provided at a position overlapping with the semiconductor pillar SP1L in the (4k+1)-th row. The position of the member SHE1U is shifted from the position of the member SHE1L in the Y direction by one row of the semiconductor pillars SP1.

In addition, in the present embodiment, in the wiring layers 24U and 24L in each of the plurality of source-side select gate lines SGS, a member SHE2U for separating adjacent upper wiring layers 24U is provided at a position overlapping with the semiconductor pillar SP2U in the 4k-th row, and a member SHE2L for separating adjacent lower wiring layers 24L is provided at a position overlapping with the semiconductor pillar SP2L in the (4k+1)-th row. The position of the member SHE2U is shifted from the position of the member SHE2L in the Y direction by one row of the semiconductor pillars SP2.

Thus, the memory device 1 of the present embodiment prevents leakage from the select transistors ST1 and ST2 connected to the select gate lines SGD and SGS adjacent to the selected select gate lines SGD and SGS, caused by the electric field generated from the selected select gate lines SGD and SGS.

As a result, the memory device 1 of the present embodiment can boost the voltage of the memory pillar MP while reducing the influence of the select transistors ST1 and ST2 in the weak on state.

In addition, as long as the positions of the members SHE1U and SHE2U between the upper wiring layers 22U and 24U are shifted by one row of pillar sets from the positions of the members SHE1L and SHE2L between the lower wiring layers 22L and 24L, the number of pillar sets in one string unit SU may be three or less, or five or more.

### (a-2) Circuit Configuration of Memory Cell Array

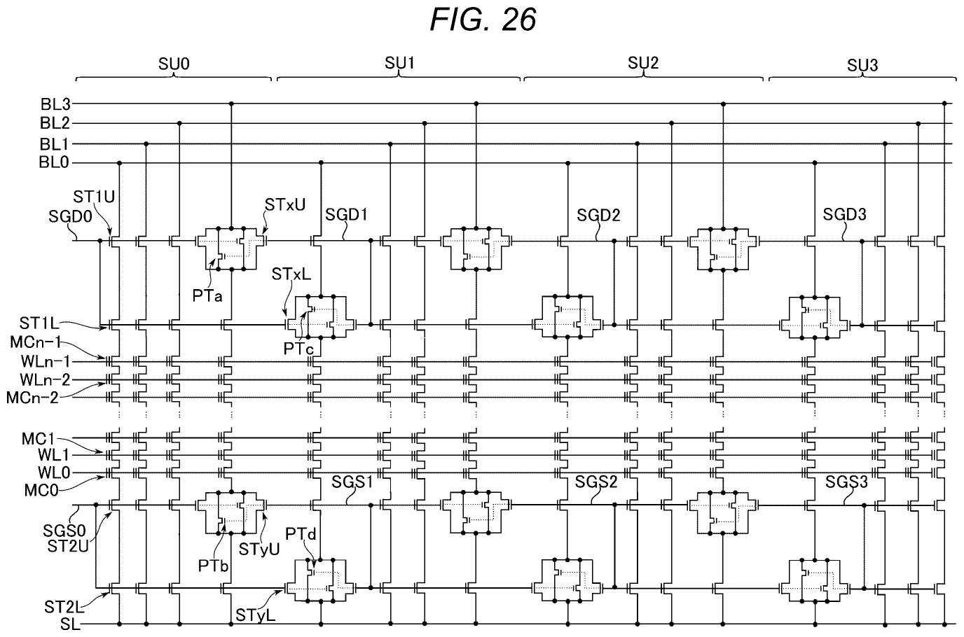

FIG. 26 is a circuit diagram of the memory cell array 10 of the memory device 1 of the present embodiment.

The example shown in FIG. 26 shows the configuration of the memory cell array 10 with respect to four bit lines BL. In the present embodiment, the memory cell array 10 includes a plurality of configurations shown in FIG. 26 that are repeatedly arranged in the X direction at a cycle of four bit lines BL.

As shown in FIG. 26, each bit line BL (BL0, BL1, BL2, BL3) is electrically connected to a corresponding NAND string NS (pillar portion PLR) in each string unit SU.

In the present embodiment, the NAND string NS includes two drain-side select transistors ST1U, ST1L and two source-side select transistors ST2U, ST2L.

In each string unit SU, the current path of one select transistor ST1U is connected in series to the current path of the other select transistor ST1L. The gates of the select transistors ST1U and ST1L are electrically connected to one corresponding drain-side select gate line SGD.

In each string unit SU, the current path of one select transistor ST2U is connected in series to the current path of the other select transistor ST2L. The gates of the select transistors ST2U and ST2L are electrically connected to one corresponding source-side select gate line SGS.

The NAND string NS corresponding to the pillar portion PLR in the 4k-th row is electrically connected to, for example, the fourth bit line BL3.

As in the structure of FIGS. 21 to 25, when the semiconductor pillar SP1U in the NAND string NS in the 4k-th row is separated into two portions p1 and p2 by the member SHE1U, the transistor STxU is connected in parallel with the select transistor ST1U. The current path of the transistor STxU is connected in series to the current path of the transistor ST1L. The gate of a transistor STxU belonging to a certain string unit SUq corresponding to a certain drain-side select gate line SGDq is electrically connected to a drain-side select gate line SGDq+1 corresponding to an adjacent string unit SUq+1. The portion where the portion p1 and the wiring layer 22U intersect functions as a transistor ST1U. The portion where the portion p2 and the wiring layer 22U intersect functions as a transistor STxU. q is an integer of 0 or more and 2 or less.

In this way, in the select transistor ST1U and transistor STxU provided on a certain semiconductor pillar SP1U, the drain-side select gate line SGD connected to the transistor STxU is different from the drain-side select gate line SGD connected to the select transistor ST1U.

For example, the NAND string NS in the 4k-th row further includes a parasitic transistor PTa in the semiconductor pillar SP1U. The parasitic transistor PTa is formed between the portion p1 and the wiring layer 22U that is not in direct contact with the portion p1, or between the portion p2 and the wiring layer 22U that is not in direct contact with the portion p2. The current path of the parasitic transistor PTa is connected in parallel to the current paths of the transistors ST1U and STxU. The gate of the parasitic transistor PTa is not directly connected to the drain-side select gate line SGD. The parasitic transistor PTa operates due to an electric field generated from the wiring layer 22U that is not in direct contact with the portions p1 and p2.

The fourth string unit SU3 does not include the transistors STxU and PTa in the NAND string NS connected to the fourth bit line BL3.

When the semiconductor pillar SP2U in the NAND string NS in the 4k-th row is separated into two portions p1 and p2 by the member SHE2U, the transistor STyU is connected in parallel with the select transistor ST2U. The current path of the transistor STyU is connected in series to the current path of the transistor ST2L. The gate of a transistor STyU belonging to a certain string unit SUq corresponding to a certain source-side select gate line SGSq is electrically connected to a source-side select gate line SGSq+1 corresponding to an adjacent string unit SUq+1. The portion where the portion p1 and the wiring layer 24U intersect functions as a transistor ST2U. The portion where the portion p2 and the wiring layer 24U intersect functions as a transistor STyU.

In this way, in the select transistor ST2U and transistor STyU provided on a certain semiconductor pillar SP2U, the source-side select gate line SGS connected to the transistor STyU is different from the source-side select gate line SGS connected to the select transistor ST2U.

For example, the NAND string NS in the 4k-th row further includes a parasitic transistor PTb in the semiconductor pillar SP2U. The parasitic transistor PTb is formed between the portion p1 and the wiring layer 24U that is not in direct contact with the portion p1, or between the portion p2 and the wiring layer 24U that is not in direct contact with the portion p2. The current path of the parasitic transistor PTb is connected in parallel to the current paths of the transistors ST2U and STyU. The gate of the parasitic transistor PTb is not directly connected to the source-side select gate line SGS. The parasitic transistor PTb operates due to an electric field generated from the wiring layer 24U that is not in direct contact with the portions p1 and p2.

The fourth string unit SU3 does not include the transistors STyU and PTb in the NAND string NS connected to the fourth bit line BL3.

When the semiconductor pillar SP1L in the NAND string NS in the (4k+1)-th row is separated into two portions p3 and p4 by the member SHE1L, the transistor STxL is connected in parallel with the select transistor ST1L. The current path of the transistor STxL is connected in series to the current path of the transistor ST1U. The gate of a transistor STxL belonging to a certain string unit SUq corresponding to a certain drain-side select gate line SGDq is electrically connected to a drain-side select gate line SGDq+1 corresponding to an adjacent string unit SUq+1. The portion where the portion p3 and the wiring layer 22L intersect functions as a transistor STxL. The portion where the portion p4 and the wiring layer 22L intersect functions as a transistor ST1L.

In this way, in the select transistor ST1L and transistor STxL provided on a certain semiconductor pillar SP1L, the drain-side select gate line SGD connected to the transistor STxL is different from the drain-side select gate line SGD connected to the select transistor ST1L.

For example, the NAND string NS in the (4k+1)-th row further includes a parasitic transistor PTc in the semiconductor pillar SP1L. The parasitic transistor PTc is formed between the portion p3 and the wiring layer 22L that is not in direct contact with the portion p3, or between the portion p4 and the wiring layer 22L that is not in direct contact with the portion p4. The current path of the parasitic transistor PTc is connected in parallel to the current paths of the transistors ST1L and STxL. The gate of the parasitic transistor PTc is not directly connected to the drain-side select gate line SGD. The parasitic transistor PTc operates due to an electric field generated from the wiring layer 22L that is not in direct contact with the portions p3 and p4.

The first string unit SU1 does not include the transistors STxL and PTc in the NAND string NS connected to the first bit line BL0.

When the semiconductor pillar SP2L in the NAND string NS in the (4k+1)-th row is separated into two portions p3 and p4 by the member SHE2L, the transistor STyL is connected in parallel to the select transistor ST2L. The current path of the transistor STyL is connected in series to the current path of the transistor ST2U. The gate of a transistor STyL belonging to a certain string unit SUq corresponding to a certain source-side select gate line SGSq is electrically connected to a source-side select gate line SGSq+1 corresponding to an adjacent string unit SUq+1. The portion where the portion p3 and the wiring layer 24L intersect functions as a transistor STyL. The portion where the portion p4 and the wiring layer 24L intersect functions as a transistor ST2L.

In this way, in the select transistor ST2L and the transistor STyL provided on a certain semiconductor pillar SP2L, the source-side select gate line SGS connected to the transistor STyL is different from the source-side select gate line SGS connected to the select transistor ST2L.

For example, the NAND string NS in the (4k+1)-th row further includes a parasitic transistor PTd in the semiconductor pillar SP2L. The parasitic transistor PTd is formed between the portion p3 and the wiring layer 24L that is not in direct contact with the portion p3, or between the portion p4 and the wiring layer 24L that is not in direct contact with the portion p4. The current path of the parasitic transistor PTd is connected in parallel to the current paths of the transistors ST2L and STyL. The gate of the parasitic transistor PTd is not directly connected to the source-side select gate line SGS. The parasitic transistor PTd operates due to an electric field generated from the wiring layer 24L that is not in direct contact with the portions p3 and p4.

The first string unit SU1 does not include the transistors STyL and PTd in the NAND string NS connected to the first bit line BL0.

### (b) Operation Example

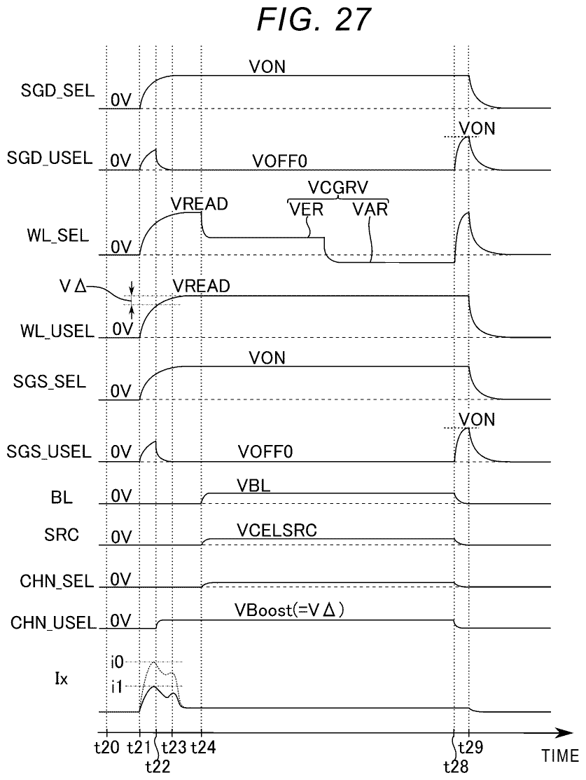

An example of the operation (control method) of the memory device 1 of the present embodiment will be described with reference to FIG. 27.

FIG. 27 is a timing chart showing an example of the operation of the memory device 1 of the present embodiment. In FIG. 27, the horizontal axis corresponds to time, and the vertical axis corresponds to the voltage value or current value of each wiring. FIG. 27 shows a read operation of the memory device 1 as an example of the operation of the memory device 1 of the present embodiment.

### Time t20

As shown in FIG. 27, at time t20, the memory device 1 starts a read operation on the operation target indicated by the address ADD based on the command CMD from the memory controller 2.

### Time t21

At time t21, the memory device 1 starts applying voltages to the plurality of wirings WL, SGD, and SGS in the selected block BLK. This changes the voltages of the plurality of wirings WL, SGD, and SGS in the selected block BLK.

The memory device 1 applies a non-selection voltage VREAD to the selected word line WL-SEL and the non-selected word line WL-USEL. The memory device 1 applies a voltage VON to the drain-side select gate lines SGD-SEL and SGD-USEL and the source-side select gate lines SGS-SEL and SGS-USEL.

In response to application of voltages to the word line WL and the select gate lines SGD and SGS, a charging current IWL for the word line WL is generated. The current value of the charging current IWL rises.

### Time t22

At a certain time t22, the voltages of the drain-side select gate lines SGD-SEL and SGD-USEL and the voltages of the source-side select gate lines SGS-SEL and SGS-USEL reach a certain voltage value. At this time t22, the memory device 1 stops applying the positive voltage to the unselected drain-side select gate line SGD-USEL and the unselected source-side select gate line SGS-USEL. The memory device 1 applies a voltage VOFF0 of 0 V to the unselected drain-side/source-side select gate lines SGD-USEL and SGS-USEL.

### Time t23

At time t23, the voltage of the unselected drain-side select gate line SGD-USEL and the voltage of the unselected source-side select gate line SGS-USEL reach 0 V.

Thus, the select transistors ST1U and ST1L connected to the unselected drain-side select gate line SGD-USEL and the unselected source-side select transistors ST2U and ST2L are turned off.

Among the transistors STxU of the NAND string NS in the 4k-th row described above, the transistor STxU connected to the selected drain-side select gate line SGD-SEL is turned on, and the transistor STxU connected to the unselected drain-side select gate line SGD-USEL is turned off.

At this time, in the unselected string units SU, the gate of the transistor ST1L connected in series to the transistor STxU connected to the selected drain-side select gate line SGD-SEL is connected to the unselected drain-side select gate line SGD-USEL. Therefore, even when the parasitic transistor STxU is ON in the unselected string unit SU, the current path of the transistor STxU is electrically isolated from the current path of the memory cell MC by the select transistor ST1L in the off state.

Similarly, among the transistors STyU of the NAND string NS in the 4k-th row, the transistor STyU connected to the selected source-side select gate line SGS-SEL is turned on, and the transistor STyU connected to the unselected source-side select gate line SGS-USEL is turned off.

In the unselected string unit SU, the gate of the transistor ST2L connected in series to the transistor STyU connected to the selected source-side select gate line SGS-SEL is connected to the unselected source-side select gate line SGS-USEL. Therefore, even when the parasitic transistor STyU is ON in the unselected string unit SU, the current path of the transistor STyU is electrically isolated from the source line SL by the select transistor ST2L in the off state.

Furthermore, among the transistors STxL of the NAND string NS in the (4k+1)-th row, the transistor STxL connected to the selected drain-side select gate line SGD-SEL is turned on, and the transistor STxL connected to the unselected drain-side select gate line SGD-USEL is turned off.

In the unselected string units SU, the gate of the transistor ST1U connected in series to the transistor STxL connected to the selected drain-side select gate line SGD-SEL is connected to the unselected drain-side select gate line SGD-USEL. Therefore, even when the parasitic transistor STxL is ON in the unselected string unit SU, the current path of the transistor STxL is electrically isolated from the bit line BL by the select transistor ST1U in the off state.

Among the transistors STyL of the NAND string NS in the (4k+1)-th row, the transistor STyL connected to the selected source-side select gate line SGS-SEL is turned on, and the transistor STyL connected to the unselected source-side select gate line SGS-USEL is turned off.

In the unselected string unit SU, the gate of the transistor ST2U connected in series to the transistor STyL connected to the selected source-side select gate line SGS-SEL is connected to the unselected source-side select gate line SGS-USEL. Therefore, even when the parasitic transistor STyL is ON in the unselected string unit SU, the current path of the transistor STyL is electrically isolated from the current path of the memory cell MC by the select transistor ST2U in the off state.

The parasitic transistors PTa, PTb, PTc, and PTd are in a weak on state due to the influence of the electric field from the selected select gate lines SGD-SEL and SGS-SEL. The parasitic transistor PTa in the weak on state is electrically isolated from the current path of the memory cell MC by the select transistor ST1L in the off state. The parasitic transistor PTb in the weak on state is electrically isolated from the source line SL by the select transistor ST2L in the off state. The parasitic transistor PTc in the weak on state is electrically isolated from the bit line BL by the select transistor ST1U in the off state. The parasitic transistor PTd in the weak on state is electrically isolated from the current path of the memory cell MC by the select transistor ST2U in the off state.

Thus, in the present embodiment, in the unselected string unit SU, at least one of the two select transistors ST1U and ST1L connected in series electrically isolates the parasitic transistors STxU, STxL, PTa, and PTc that are formed in the NAND string NS (pillar portion PLR) from the current path of the bit line BL or memory cell MC. In the unselected string unit SU, at least one of two select transistors ST2U and ST2L connected in series electrically isolates parasitic transistors STyU, STyL, PTb, and PTd that are formed in the NAND string NS (pillar portion PLR) from the current path of the source line SL or the memory cell MC.

This reduces leakage from the NAND strings NS (pillar portions PLR) in the unselected string units SU.

During the period from time t22 to time t23, in response to the select transistors ST1U, ST1L, ST2U, and ST2L in the off-state, the semiconductor layer CHN-USEL of the memory pillar MP connected to the unselected select gate lines SGD-USEL and SGS-USEL rises in response to the charging voltage ΔV of the non-selected word line WL-USEL. For example, the voltage of the semiconductor layer CHN-USEL reaches the voltage VBoost.

The voltages of the word lines WL-SEL and WL-USEL reach the voltage VREAD. The voltage of the selected drain-side select gate line SGD-SEL and the voltage of the selected source-side select gate line SGS-SEL reach the voltage VON.

### Time t24

At time t24, the memory device 1 applies a read voltage VCGRV to the selected word line WL-SEL. The memory device 1 applies a voltage VBL to the bit line BL and a voltage VCELSRC to the source line SL. The read voltage VCGR includes one or more read levels depending on the page to be read.

### Time t28

At time t28, the memory device 1 stops the application of the read voltage VCGRV to the selected word line WL-SEL, the application of the voltage VBL to the bit line BL, and the application of the voltage VCELSRC to the source line SL. The memory device 1 starts applying the non-selection voltage VREAD to the selected word line WL-SEL. This causes the voltage of the selected word line WL-SEL to rise to the non-selection voltage VREAD.

The memory device 1 stops applying the voltage VOFF to the unselected drain-side select gate lines SGD-USEL and the unselected source-side select gate lines SGS-USEL. The memory device 1 starts applying a positive voltage (for example, voltage VREAD) to the unselected drain-side/source-side select gate lines SGD-USEL and SGS-USEL. Thus, the voltages of the unselected drain-side/source-side select gate lines SGD-USEL and SGS-USEL rise to a positive voltage. The transistors ST1U, ST1L, STxU, and STxL connected to the unselected drain-side select gate line SGD-USEL, and the select transistors ST2U, ST2L, STyU, and STyL connected to the source-side select gate line SGS-USEL are turned on by the applied positive voltage.

### Time t29

At time t29, the memory device 1 stops applying voltages to the word lines WL-SEL and WL-USEL, the drain-side select gate lines SGD-SEL and SGD-USEL, and the source-side select gate lines SGS-SEL and SGS-USEL. Thus, the voltage of each of the wirings WL, SGD, and SGS is set to 0 V.

The memory device 1 transfers the data output from the memory cell array 10 to the memory controller 2 as read data.

Through the above operations, the memory device 1 of the present embodiment completes the read operation.

The example of the operation of the memory device 1 of the present embodiment may be applied to a verification operation of a write operation of the memory device 1.

### (c) Modifications

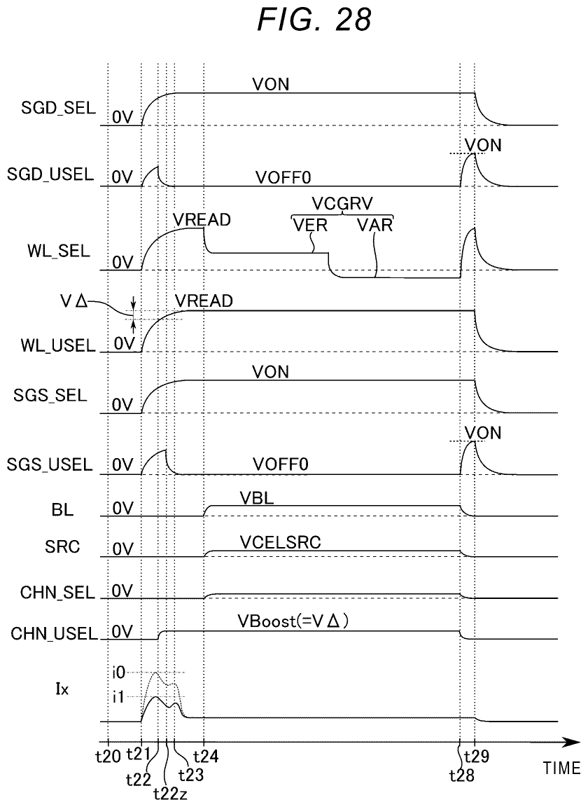

A modification of the memory device 1 of the present embodiment will be described with reference to FIG. 28.

FIG. 28 is a timing chart showing a modification of the example of the operation of the memory device 1 of the present embodiment.

As shown in FIG. 28, the timing of application of the voltage VOFF0 to the unselected drain-side select gate lines SGD-USEL may be different from the timing of application of the voltage VOFF0 to the unselected source-side select gate lines SGS-SEL.

In the example of FIG. 28, the memory device 1 applies a voltage VOFF0 to the unselected drain-side select gate line SGD-USEL at time t22. After that, at time t22z, the memory device 1 applies the voltage VOFF0 to the unselected source-side select gate line SGS-USEL.

Note that after the voltage VOFF0 is applied to the unselected source-side select gate lines SGS-USEL, the voltage VOFF0 may be applied to the unselected drain-side select gate lines SGD-USEL.

This allows the memory device 1 of the present embodiment to ensure operational stability and reliability.

### (d) Summary

In the memory device 1 of the present embodiment, each drain-side select gate line SGD includes two wiring layers 22U and 22L stacked in the Z direction, and each source-side select gate line SGS includes two wiring layers 24U and 24L stacked in the Z direction. Select transistors ST1U and ST1L are provided at the intersections of the wiring layers 22U and 22L and the semiconductor pillars SP1U and SP1L, respectively. Select transistors ST2U and ST2L are provided at the intersections of the wiring layers 24U and 24L and the semiconductor pillars SP2U and SP2L, respectively.

A member SHE1U for separating the upper wiring layer 22U configuring the drain-side select gate line SGD is provided to overlap with the semiconductor pillar SP1U of the pillar portion PLR in the 4k-th row. A member SHE1L for separating the lower wiring layer 22L configuring the drain-side select gate line SGD is provided to overlap with the semiconductor pillar SP1L of the pillar portion PLR in the (4k+1)-th row.

Due to the arrangement of the members SHE1U and SHE1L, parasitic transistors STxU, STxL, STa, and STc are formed in the semiconductor pillars SP1U and SP1L.

As in the present embodiment, the division position between the plurality of select gate lines SGD is different in the upper wiring layer 22U and the lower wiring layer 22L, so that one select transistor ST1 out of the select transistors ST1U and ST1L in the off state electrically isolates the transistors STxU, STxL, STa and STc in the on state from the current path of the bit line BL or the memory cell MC.

Therefore, in the memory device 1 of the present embodiment, it is possible to prevent the leakage from occurring on the drain side of the memory pillar MP of the NAND string NS of the unselected string unit SU.

Further, a member SHE2U for separating the upper wiring layer 22U configuring the source-side select gate line SGS is provided to overlap with the semiconductor pillar SP2U of the pillar portion PLR in the 4k-th row. A member SHE2L for separating the lower wiring layer 24L configuring the source-side select gate line SGS is provided to overlap with the semiconductor pillar SP2L of the pillar portion PLR in the (4k+1)-th row.

Due to the arrangement of the members SHE2U and SHE2L, parasitic transistors STyU, STyL, STb, and STd are formed in the semiconductor pillars SP2U and SP2L.

Since the division position between the plurality of select gate lines SGS is different in the upper wiring layer 24U and the lower wiring layer 24L, one select transistor ST2 out of the select transistors ST2U, ST2L in the off state electrically isolates the transistors STyU, STyL, STb and STd in the on state from the current path of the source line SL or the memory cell MC.

Therefore, in the memory device 1 of the present embodiment, the leakage that occurs on the source side of the memory pillar MP of the NAND string NS of the unselected string unit SU can be reduced.

Therefore, in the memory device 1 of the present embodiment, the channel boost failure in the memory pillar MP caused by leakage can be reduced.

Furthermore, in the memory device 1 of the present embodiment, a dummy member for isolating the select gate lines SG may not be provided in the memory cell array 10. Therefore, in the memory device 1 of the present embodiment, an increase in manufacturing costs due to the placement of dummy members can be reduced.

As described above, in the memory device 1 of the present embodiment, the operating characteristics of the memory device can be improved.

### (7) Seventh Embodiment

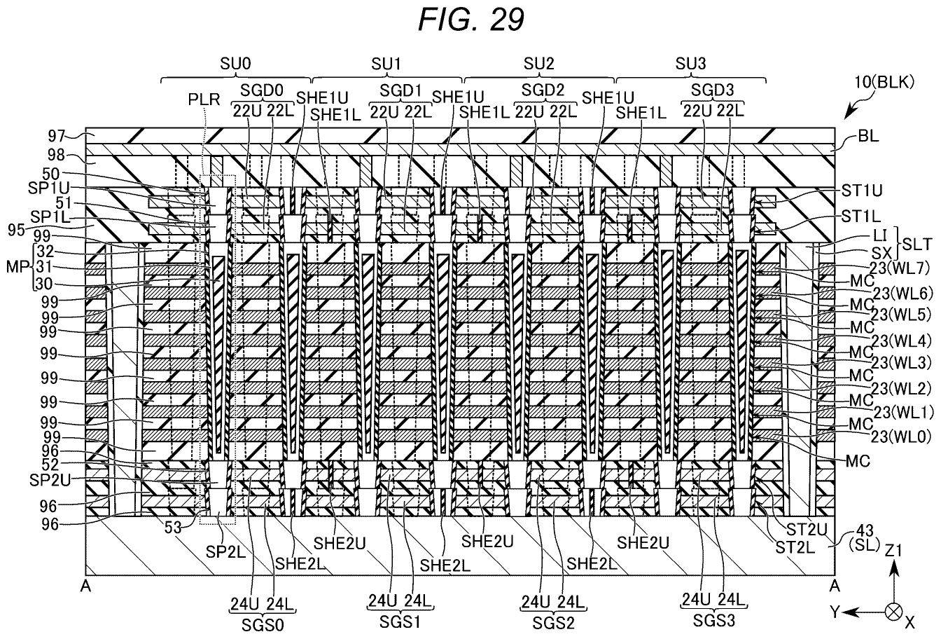

A memory device according to a seventh embodiment will be described with reference to FIGS. 29 to 31.

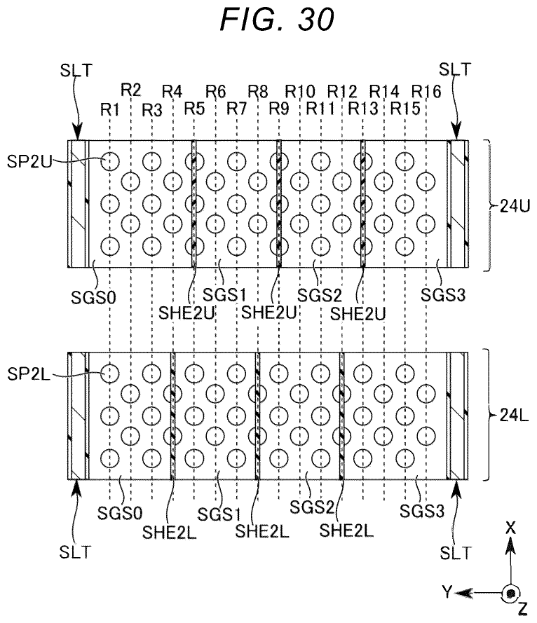

FIG. 29 is a cross-sectional view showing the cross-sectional structure of the memory cell array 10 in the memory device 1 of the present embodiment. FIG. 30 is a plan view schematically showing the structure of the wiring layers 24U and 24L in the hierarchy where the wiring layer 24U is provided and in the hierarchy where the wiring layer 24L is provided, with respect to the source-side select gate line SGS. In FIG. 30, the insulating layers 52 and 53 are omitted.

As shown in FIGS. 29 and 30, in the memory device 1 of the present embodiment, the positions of the members SHE2U and SHE2L provided in the wiring layers 24U and 24L that configure the source-side select gate line SGS are different from the positions of the members SHE1U and SHE1L provided within the wiring layers 22U and 22L that configure the drain-side select gate line SGD.

As described above, in order to separate the upper wiring layers 22U of the drain-side select gate lines SGD, the member SHE1U is provided to overlap with the upper semiconductor pillar SP1U belonging to the pillar portion PLR (NAND string NS) in the 4k-th row. In order to separate the lower wiring layers 22L of the drain-side select gate lines SGD, a member SHE1L is provided to overlap with the lower semiconductor pillar SP1L belonging to the pillar portion PLR in the (4k+1)-th row.

In the present embodiment, in order to separate the upper wiring layers 24U of the source-side select gate lines SGS, a member SHE2U is provided to overlap with the upper semiconductor pillar SP2 belonging to the pillar portion PLR in the (4k+1)-th row. In order to separate the lower wiring layers 24L of the source-side select gate lines SGS, a member SHE2L is provided to overlap with the lower semiconductor pillar SP2L belonging to the pillar portion PLR in the 4k-th row.

In this way, the position of the member SHE2U overlaps with the position of the member SHE1L in the Z direction. Furthermore, the position of the member SHE2L overlaps with the position of the member SHE1U in the Z direction.

In addition, with regard to the wiring layers 22U and 22L of the drain-side select gate line SGD, the member SHE1U may be provided to overlap with the upper semiconductor pillar SP1U belonging to the pillar portion PLR in the (4k+1)-th row, and the member SHE1L may be provided to overlap with the lower semiconductor pillar SP1L belonging to the pillar portion PLR in the 4k-th row.

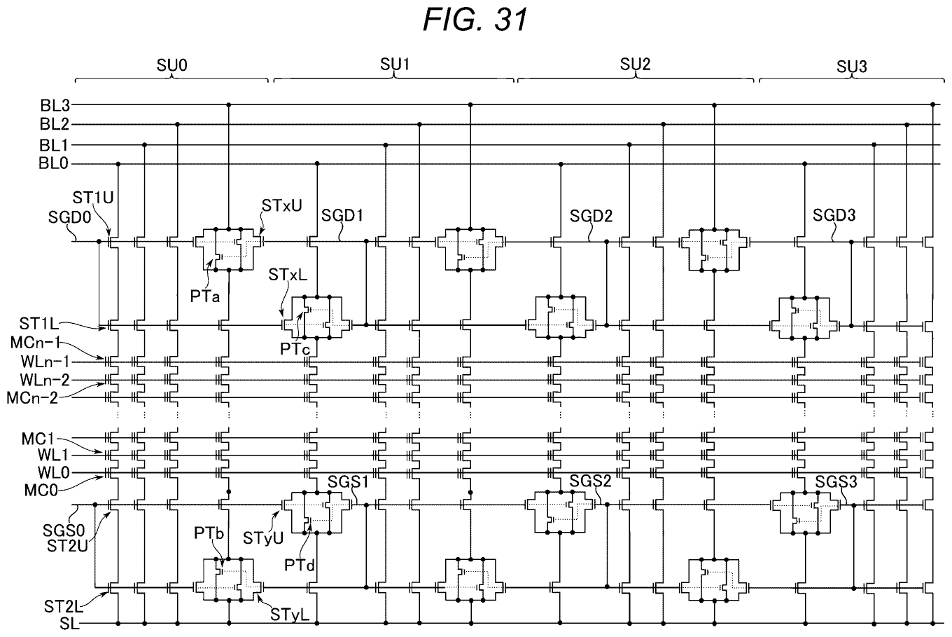

FIG. 31 is a circuit diagram of the memory cell array 10 in the memory device 1 of the present embodiment.

As shown in FIG. 31, in the select transistors ST2U and ST2L on the source side of the NAND string NS in the 4k-th row, a transistor STyL is connected in parallel to the select transistor ST2L. In addition, in the select transistors ST2U and ST2L on the source side of the NAND string NS in the (4k+1)-th row, a transistor STyU is connected in parallel to the select transistor ST2U.

The parasitic transistor STb is connected in parallel to the select transistor ST2L. The parasitic transistor STd is connected in parallel to the select transistor ST2U.

During operation (for example, a read operation) of the memory device 1 of the present embodiment, in the NAND string NS (pillar portion PLR) in the 4k-th row, the transistor STyL connected to the selected source-side select gate line SGS-SEL is electrically isolated from the current path of the memory cell MC by the select transistor ST2U connected to the unselected select gate line SGS-USEL.

Therefore, in the unselected string units SU, the semiconductor layer 31 of the memory pillar MP of the NAND string NS in the 4k-th row is channel boosted without causing leakage.

In the NAND string NS in the (4k+1)-th row, the transistor STyU connected to the selected source-side select gate line SGS-SEL is electrically isolated from the source line SL by the select transistor ST2L connected to the unselected select gate line SGS-USEL.

Therefore, in the unselected string units SU, the semiconductor layer 31 of the memory pillar MP of the NAND string NS in the (4k+1)-th row is channel boosted without causing leakage.

Therefore, in the memory device 1 of the present embodiment, substantially the same effects as the above-described embodiment can be obtained.

As described above, in the memory device 1 of the present embodiment, the operating characteristics can be improved.

### (8) Eighth embodiment

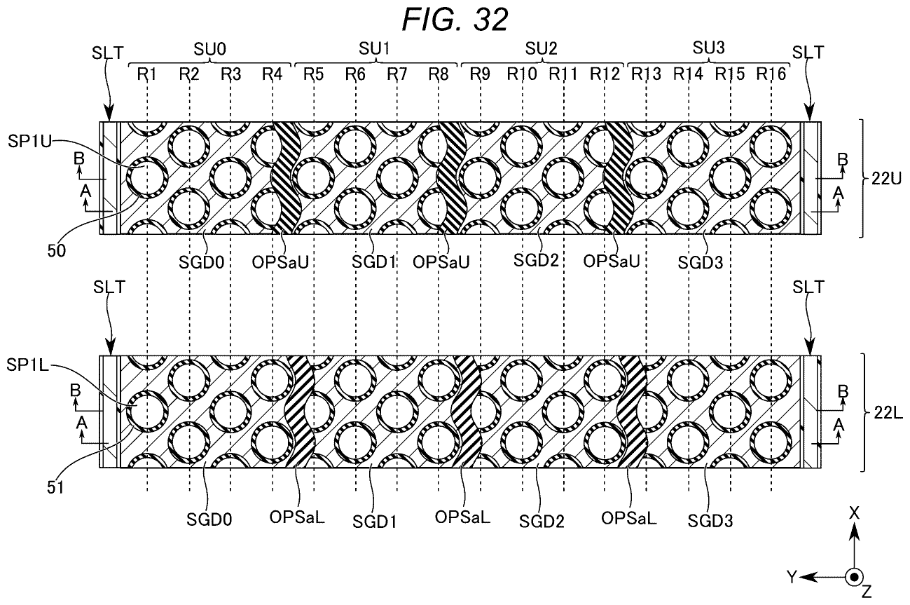

A memory device according to an eighth embodiment will be described with reference to FIGS. 32 to 36.

FIG. 32 is a plan view schematically showing each of the hierarchies of the wiring layers 22U and 22L that configure the drain-side select gate line SGD in the memory device 1 of the present embodiment.

As shown in FIG. 32, members OPSaU and OPSaL meandering in the XY plane are provided between adjacent wiring layers 22U and between adjacent wiring layers 22L, respectively.

Each of the members OPSaU and OPSaL extends in the X direction. The members OPSaU and OPSaL include an insulator.

The member OPSaU is provided between the wiring layers 22U. The member OPSaU is provided within a slit that meanders and extends in the X direction. The member OPSaU is disposed, for example, in an area between the pillar portion PLR in the 4k-th row and the pillar portion PLR in the (4k+1)-th row. The member OPSaU overlaps with an end of the semiconductor pillar SP1U of the pillar portion PLR in the 4k-th row on the boundary side between the string units SU. The end of the semiconductor pillar SP1U of the pillar portion PLR in the 4k-th row is partially chipped off by the member OPSaU. The planar shape of the semiconductor pillar SP1U in the 4k-th row when viewed from the Z direction has a partial circular shape. The member OPSaU does not overlap with the semiconductor pillar SP1U of the pillar portion PLR in the (4k+1)-th row. The semiconductor pillar SP1U of the pillar portion PLR in the (4k+1)-th row is not chipped due to the member OPSaU. The planar shape of the semiconductor pillar SP1U in the (4k+1)-th row when viewed from the Z direction has a circular (or elliptical) shape.

The member OPSaL is provided between the wiring layers 22L. The member OPSaL is provided within a slit that meanders and extends in the X direction. The member OPSaL is disposed in an area between the pillar portion PLR in the 4k-th row and the pillar portion PLR in the (4k+1)-th row. The member OPSaL does not overlap with the semiconductor pillar SP1L of the pillar portion PLR in the 4k-th row. The end of the semiconductor pillar SP1L of the pillar portion PLR in the 4k-th row is not chipped due to the member OPSaL. The planar shape of the semiconductor pillar SP1L in the 4k-th row has a circular shape as viewed in the Z direction. The member OPSaL overlaps with an end of the semiconductor pillar SP1L of the pillar portion PLR in the (4k+1)-th row on the boundary side between the string units SU. The end of the semiconductor pillar SP1L of the pillar portion PLR in the (4k+1)-th row is partially chipped off by the member OPSaL. The planar shape of the semiconductor pillar SP1L in the (4k+1)-th row when viewed from the Z direction has a partial circular shape.

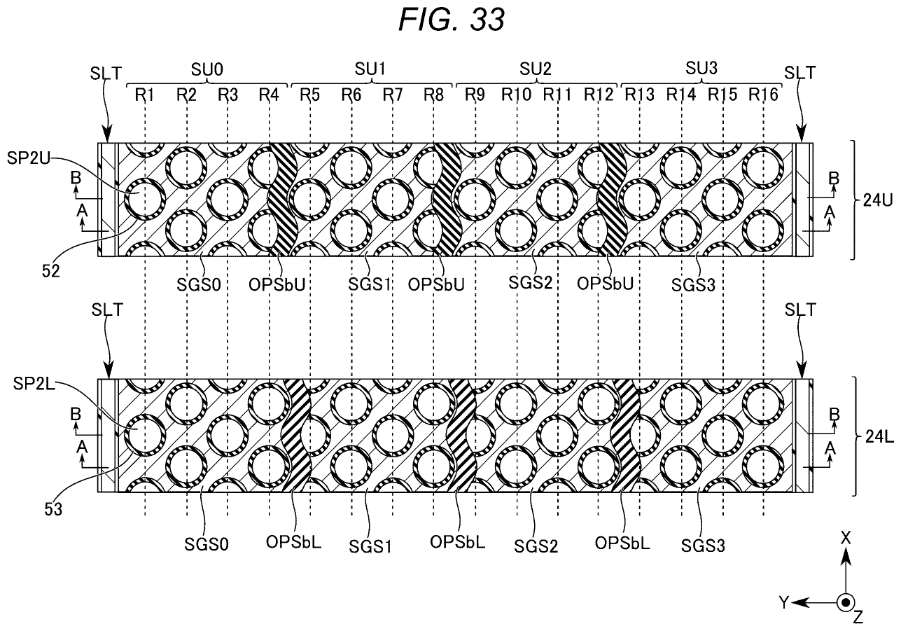

FIG. 33 is a plan view schematically showing each of the hierarchies of the wiring layers 24U and 24L that configure the source-side select gate line SGS in the memory device 1 of the present embodiment.

As shown in FIG. 33, similarly to FIG. 32, members OPSbU and OPSbL meandering in the XY plane are provided between adjacent wiring layers 24U and between adjacent wiring layers 24L, respectively.

Each of the members OPSbU and OPSbL extends in the X direction. The members OPSbU and OPSbL include an insulator.

The member OPSbU is provided between the wiring layers 24U. The member OPSbU is provided within a slit that meanders and extends in the X direction. The member OPSbU is disposed in an area between the pillar portion PLR in the 4k-th row and the pillar portion PLR in the (4k+1)-th row. The member OPSbU overlaps with an end of the semiconductor pillar SP2U of the pillar portion PLR in the 4k-th row on the boundary side between the string units SU. The end of the semiconductor pillar SP2U of the pillar portion PLR in the 4k-th row is partially chipped off by the member OPSbU. The planar shape of the semiconductor pillar SP2U in the 4k-th row when viewed from the Z direction has a partial circular shape. The member OPSbU does not overlap with the semiconductor pillar SP2U of the pillar portion PLR in the (4k+1)-th row. The semiconductor pillar SP2U of the pillar portion PLR in the (4k+1)-th row is not chipped due to the member OPSbU. The planar shape of the semiconductor pillar SP2U in the (4k+1)-th row when viewed from the Z direction has a circular shape.

The member OPSbL is provided between the wiring layers 24L. The member OPSbL is provided inside a slit that meanders and extends in the X direction. The member OPSbL is disposed in an area between the pillar portion PLR in the 4k-th row and the pillar portion PLR in the (4k+1)-th row. The member OPSbL does not overlap with the semiconductor pillar SP2L of the pillar portion PLR in the 4k-th row. The end of the semiconductor pillar SP2L of the pillar portion PLR in the 4k-th row is not chipped due to the member OPSbL. The planar shape of the semiconductor pillar SP1L in the 4k-th row has a circular shape as viewed in the Z direction. The member OPSbL overlaps with an end of the semiconductor pillar SP2L of the pillar portion PLR in the (4k+1)-th row on the boundary side between the string units SU. The end of the semiconductor pillar SP2L of the pillar portion PLR in the (4k+1)-th row is partially chipped off by the member OPSbL. The planar shape of the semiconductor pillar SP1L in the (4k+1)-th row when viewed from the Z direction has a partial circular shape.

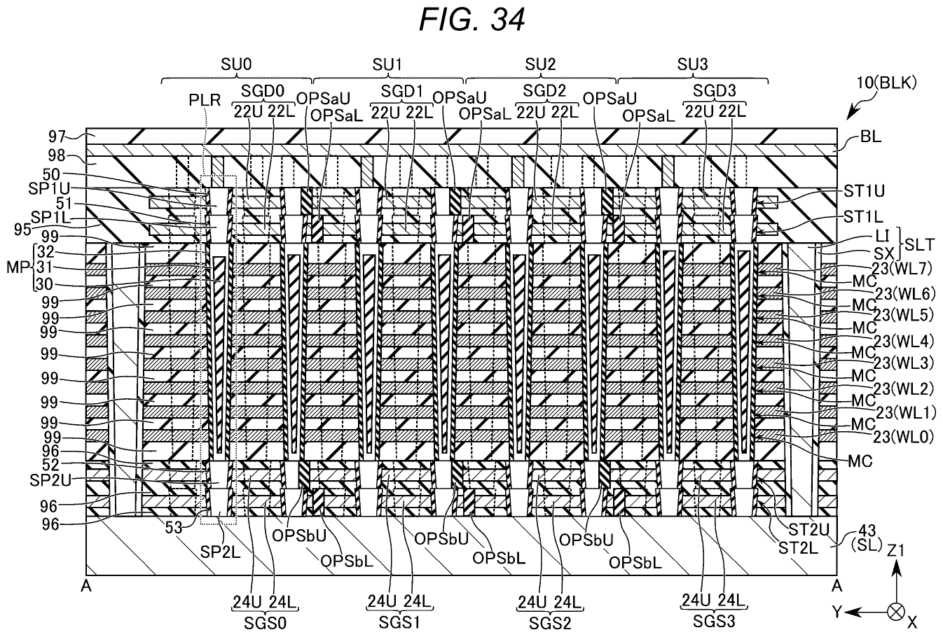

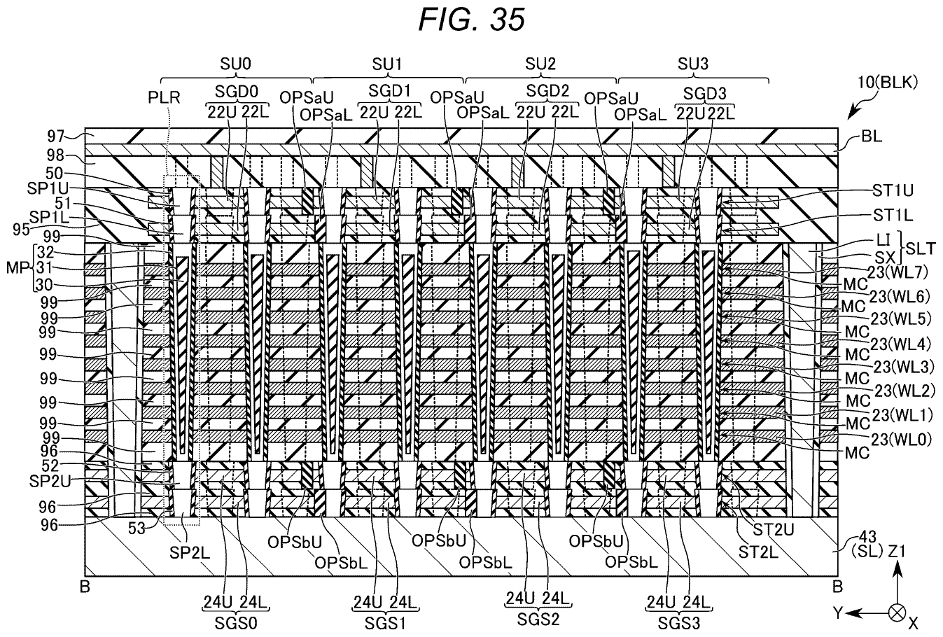

FIGS. 34 and 35 are cross-sectional views showing the cross-sectional structure of the memory device 1 of the present embodiment. FIG. 34 shows a cross-sectional structure of the memory cell array 10 taken along line A-A in FIGS. 32 and 33. FIG. 35 shows a cross-sectional structure of the memory cell array 10 taken along the line B-B in FIGS. 32 and 33.

As shown in FIGS. 34 and 35, in the hierarchy of the upper wiring layer 22U of the drain-side select gate line SGD, the member OPSaU is in direct contact with the side surface of the semiconductor pillar SP1U of the pillar portion PLR in the 4k-th row. The member OPSaU does not come into contact with the side surface of the upper semiconductor pillar SP1U of the pillar portion PLR in the (4k+1)-th row. For example, the wiring layer 22U and the insulating layer 95 are present between the member OPSaU and the side surface of the semiconductor pillar SP1U of the pillar portion PLR in the (4k+1)-th row.

In the hierarchy of the lower wiring layer 22L of the drain-side select gate line SGD, the member OPSaL is in direct contact with the side surface of the semiconductor pillar SP1L of the pillar portion PLR in the (4k+1)-th row. The member OPSaL does not come into contact with the side surface of the semiconductor pillar SP1L of the pillar portion PLR in the 4k-th row. For example, the wiring layer 22L and the insulating layer 95 are present between the member OPSaL and the side surface of the semiconductor pillar SP1L of the pillar portion PLR in the 4k-th row.

In the hierarchy of the upper wiring layer 24U of the source-side select gate line SGS, the member OPSbU is in direct contact with the side surface of the semiconductor pillar SP2U of the pillar portion PLR in the 4k-th row. The member OPSbU does not come into contact with the side surface of the semiconductor pillar SP2U of the pillar portion PLR in the (4k+1)-th row. For example, the wiring layer 24U and the insulating layer 96 are present between the member OPSbU and the side surface of the semiconductor pillar SP2U in the (4k+1)-th row.

In the hierarchy of the lower wiring layer 24L of the source-side select gate line SGS, the member OPSbL is in direct contact with the side surface of the semiconductor pillar SP2L of the pillar portion PLR in the (4k+1)-th row. The member OPSbL does not come into contact with the side surface of the semiconductor pillar SP2L of the pillar portion PLR in the 4k-th row. For example, the wiring layer 24L and the insulating layer 96 are present between the member OPSbL and the side surface of the semiconductor pillar SP2L in the 4k-th row.

Furthermore, the members OPSaU and OPSbU may be provided to overlap with the ends of the semiconductor pillars SP1U and SP2U in the (4k+1)-th row, and the members OPSaL and OPSbL may be provided to overlap with the ends of the semiconductor pillars SP1L and SP2L in the 4k-th row.

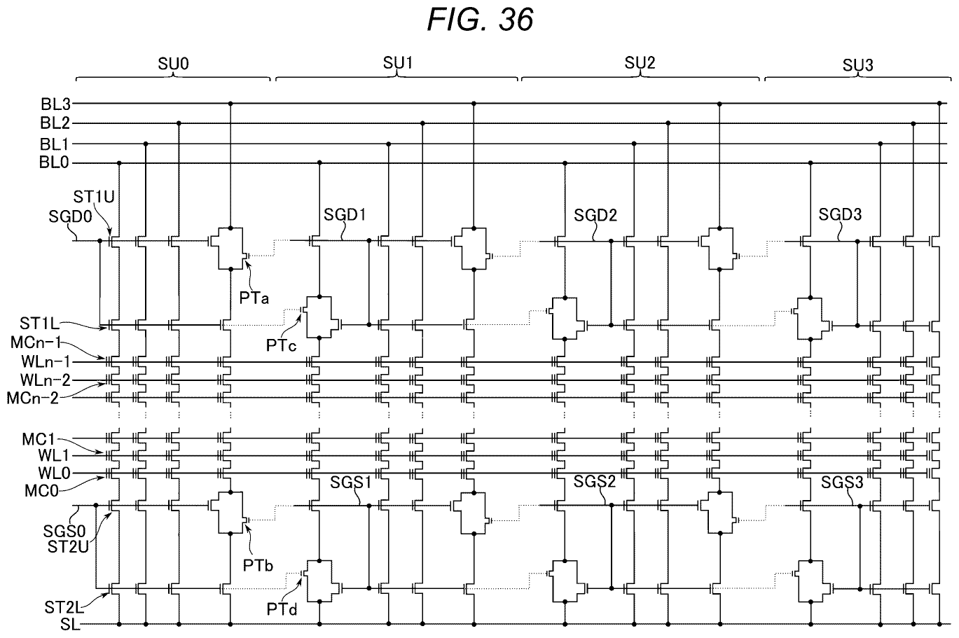

FIG. 36 is a circuit diagram showing the circuit configuration of the memory cell array 10 in the memory device 1 of the present embodiment.

As shown in FIG. 36, on the drain side of the NAND string NS in the 4k-th row of a certain string unit SU, one select transistor ST1U is connected between the bit line BL and the select transistor ST1L. The NAND string NS in the 4k-th row of a certain string unit SU does not include a transistor connected to the drain-side select gate line SGD of another string unit SU.

In this way, due to the meandering member OPSaU, a transistor (for example, transistor STxU in FIG. 26) connected in parallel to the select transistor ST1U is not formed in the semiconductor pillar SP1U common to the select transistor ST1U.

On the source side of the NAND string NS in the 4k-th row of a certain string unit SU, one select transistor ST2U is connected between the memory cell MC and the select transistor ST2L. The NAND string NS in the 4k-th row of a certain string unit SU does not include a transistor connected to the source-side select gate line SGS of another string unit SU.

In this way, due to the meandering member OPSbU, a transistor (for example, the transistor STyU in FIG. 26) connected in parallel to the select transistor ST2U is not formed in the semiconductor pillar SP2U common to the select transistor ST2U.

On the drain side of the NAND string NS in the (4k+1)-th row of a certain string unit SU, one select transistor ST1L is connected between the select transistor ST1U and the memory cell MC. The NAND string NS in the (4k+1)-th row of a certain string unit SU does not include a transistor connected to the drain-side select gate line SGD of another string unit SU.

In this way, due to the meandering member OPSaL, a transistor (for example, transistor STxL in FIG. 26) connected in parallel to the select transistor ST1L is not formed in the semiconductor pillar SP1L common to the select transistor ST1L.

On the source side of the NAND string NS in the (4k+1)-th row of a certain string unit SU, one select transistor ST2L is connected between the select transistor ST2U and the source line SL. The NAND string NS in the (4k+1)-th row of a certain string unit SU does not include a transistor connected to the source-side select gate line SGS of another string unit SU.

In this way, due to the meandering member OPSbL, a transistor (for example, the transistor STyL in FIG. 26) connected in parallel to the select transistor ST2L is not formed in the semiconductor pillar SP2L common to the select transistor ST2L.

In the present embodiment, the meandering member OPSbL divides the wiring layers 22U, 22L, 24U, and 24L for each corresponding select gate line SG such that the pillar portion PLR adjacent to the boundary of the string unit SU is not divided into a plurality of parts.

Therefore, in the memory device 1 of the present embodiment, parasitic transistors that do not contribute to the operation can be reduced. Therefore, in the memory device 1 of the present embodiment, the operation of the memory device 1 can be stabilized.

As described above, in the memory device 1 of the present embodiment, the operating characteristics of the memory device can be improved.

### (9) Ninth Embodiment

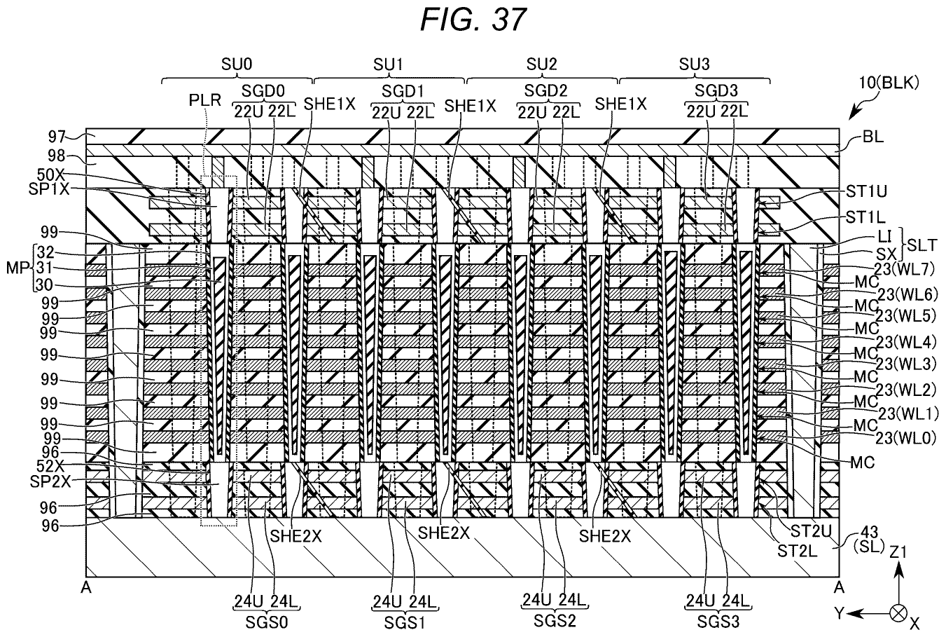

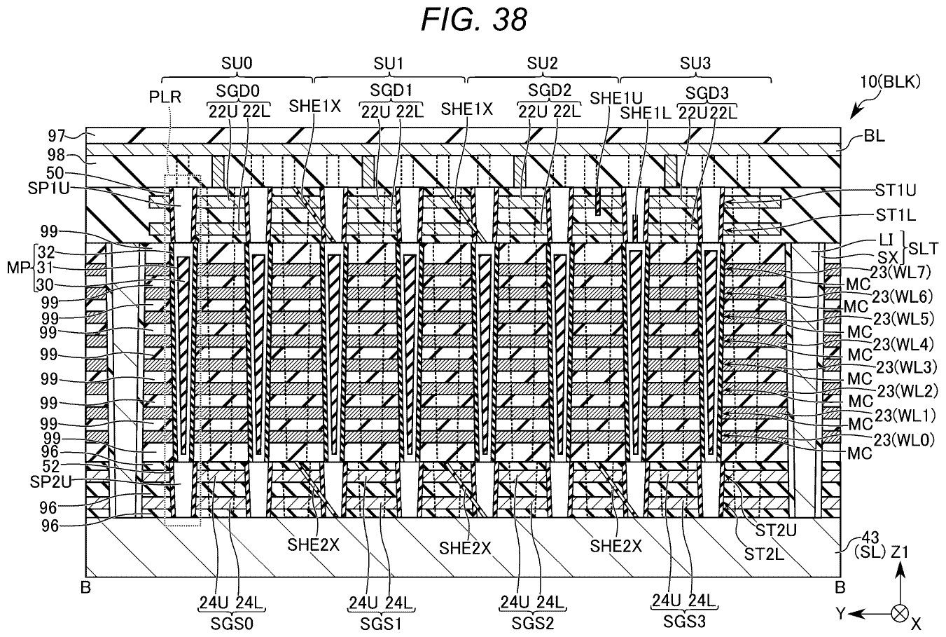

A memory device according to a ninth embodiment will be described with reference to FIGS. 37 and 38.

FIGS. 37 and 38 are cross-sectional views showing structure examples of the memory device 1 of the present embodiment. FIG. 37 shows a cross section of the memory cell array 10 along a certain YZ plane. FIG. 38 shows a cross section of the memory cell array 10 along the YZ plane different from that of FIG. 37.

As shown in FIGS. 37 and 38, in the memory device 1 of the present embodiment, members SHE1X and SHE2X for isolating each select gate line SG are inclined obliquely with respect to the Z direction when viewed from the X direction.

The members SHE1X and SHE2X extend in the X direction. The members SHE1X and SHE2X are inclined with respect to the Z direction from the pillar portion PLR in the 4k-th row toward the pillar portion PLR in the (4k+1)-th row.

Each pillar portion PLR includes a semiconductor pillar SP1X and a semiconductor pillar SP2X. The memory pillar MP is provided between the semiconductor pillar SP1X and the semiconductor pillar SP2X in the Z direction. The semiconductor pillar SP1X is provided above the memory pillar MP in the Z direction. The semiconductor pillar SP2X is provided below the memory pillar MP in the Z direction.

The semiconductor pillar SP1X penetrates the wiring layer 22U and the wiring layer 22L of the drain-side select gate line SGD. The side surface of the semiconductor pillar SP1X is covered with an insulating layer 50X. The insulating layer 50X is provided between the semiconductor pillar SP1X and the wiring layer 22U, and between the semiconductor pillar SP1X and the wiring layer 22L.

The intersection of the semiconductor pillar SP1X and the wiring layer 22U functions as a select transistor ST1U. The intersection of the semiconductor pillar SP1X and the wiring layer 22L functions as a select transistor ST1L.

The semiconductor pillar SP2X penetrates the wiring layer 24U and the wiring layer 24L of the source-side select gate line SGS. The side surface of the semiconductor pillar SP2X is covered with an insulating layer 52X. The insulating layer 52X is provided between the semiconductor pillar SP2X and the wiring layer 22U, and between the semiconductor pillar SP2X and the wiring layer 24L.

The intersection of the semiconductor pillar SP2X and the wiring layer 24U functions as a select transistor ST2U. The intersection of the semiconductor pillar SP2X and the wiring layer 24L functions as a select transistor ST2L.

Furthermore, as in the above-described embodiment, each of the semiconductor pillars SP1X and SP2X may be configured with two stacked semiconductor pillars.

In the hierarchy of the drain-side select gate line SGD, the inclined member SHE1X extends obliquely from the upper side of the semiconductor pillar SP1X in the 4k-th row toward the lower side of the semiconductor pillar SP1X in the (4k+1)-th row.

The member SHE1X is provided in a slit inclined with respect to the Z direction. The member SHE1X spans across the hierarchy of the upper wiring layer 22U and the hierarchy of the lower wiring layer 22L.

The member SHE1X electrically isolates the plurality of wiring layers 22U from each other along the arrangement direction of the pillar portions PLR in the 4k-th row. The upper portion of the member SHE1X is provided on the semiconductor pillar SP1X of the pillar portion PLR in the 4k-th row, and is also provided between the wiring layers 22U.

The member SHE1X electrically isolates the plurality of wiring layers 22L from each other along the arrangement direction of the pillar portions PLR in the (4k+1)-th row. The lower portion of the member SHE1X is provided on the semiconductor pillar SP1X of the pillar portion PLR in the (4k+1)-th row, and is provided between the wiring layers 22L.

The upper portion of the member SHE1X is located within the semiconductor pillar SP1X in the 4k-th row. The upper portion of the member SHE1X is desirably located on the semiconductor pillar SP1X side in the (4k+1)-th row from the center of the semiconductor pillar SP1X in the 4k-th row. The lower portion of the member SHE1X is located within the semiconductor pillar SP1X in the (4k+1)-th row. The lower portion of the member SHE1X is desirably located on the semiconductor pillar SP21 side in the 4k-th row from the center of the semiconductor pillar SP1X in the (4k+1)-th row.

In each of the semiconductor pillars SP1X overlapping with the member SHE1X, a current path between the bit line BL and the memory pillar MP is secured within the semiconductor pillar SP1X.

In the hierarchy of the source-side select gate line SGS, the inclined member SHE2X extends obliquely from the upper side of the semiconductor pillar SP2X in the 4k-th row toward the lower side of the semiconductor pillar SP2X in the (4k+1)-th row.

The member SHE2X is provided in a slit inclined with respect to the Z direction. The member SHE2X spans across the hierarchy of the upper wiring layer 24U and the hierarchy of the lower wiring layer 24L.

The member SHE2X electrically isolates the plurality of wiring layers 24U from each other along the arrangement direction of the pillar portions PLR in the 4k-th row. The upper portion of the member SHE2X is provided on the semiconductor pillar SP2X of the pillar portion PLR in the 4k-th row, and is also provided between the wiring layers 24U.

The member SHE2X electrically isolates the plurality of wiring layers 24L from each other along the arrangement direction of the pillar portions PLR in the (4k+1)-th row. The lower portion of the member SHE2X is provided on the semiconductor pillar SP2X of the pillar portion PLR in the (4k+1)-th row, and is also provided between the wiring layers 24L.

The upper portion of the member SHE2X is located within the semiconductor pillar SP2X in the 4k-th row. The upper portion of the member SHE2X is desirably located on the semiconductor pillar SP2X side in the (4k+1)-th row from the center of the semiconductor pillar SP2X in the 4k-th row. The lower portion of the member SHE2X is located within the semiconductor pillar SP2X in the (4k+1)-th row. The lower portion of the member SHE2X is desirably located on the semiconductor pillar SP2X side in the 4k-th row from the center of the semiconductor pillar SP2X in the (4k+1)-th row.

In each of the semiconductor pillars SP2X overlapping with the member SHE2X, a current path between the source line SL and the memory pillar MP is ensured within the semiconductor pillar SP2X.

The inclined members SHE1X and SHE2X are provided within the boundary between adjacent string units SU.

In the semiconductor pillars SP1X, SP2X within the 4k-th row of a certain string unit SU, the portions (semiconductor portions) facing the wiring layers 22U, 22L, 24U, and 24L belonging to an adjacent string unit SU are electrically isolated from the current path of the portions facing the wiring layers 22U, 22L, 24U, and 24L belonging to the certain string unit SU by the members SHE1X and SHE2X extending obliquely from the area in the 4k-th row to the area in the (4k+1)-th row.

In semiconductor pillars SP1X and SP2X within the (4k+1)-th row of a certain string unit SU, the portions facing the wiring layers 22U, 22L, 24U, and 24L belonging to an adjacent string unit SU are electrically isolated from the current path of the portions facing the wiring layers 22U, 22L, 24U, and 24L belonging to the certain string unit SU by the members SHE1X and SHE2X extending from the area in the 4k-th row to the area in the (4k+1)-th row.

Therefore, the parasitic transistors connected in parallel to the select transistors ST1 and ST2 are not formed in the same semiconductor pillars SP1X and SP2X as the select transistors ST1 and ST2.

Thus, in the memory device 1 of the present embodiment, the channel boost failure in the semiconductor layer of the memory pillar MP caused by leakage from a transistor (for example, a parasitic transistor) can be reduced.

Therefore, the memory device 1 of the present embodiment can improve the characteristics of the memory device.

### (10) Others

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory device comprising:
a first string including a plurality of first memory cells and a first transistor, the first transistor connected to one end of the plurality of first memory cells;
a second string including a plurality of second memory cells and a second transistor, the second transistor connected to one end of the plurality of second memory cells;
a plurality of word lines connected to respective gates of the plurality of first memory cells and respective gates of the plurality of second memory cells;
a first wiring connected to a gate of the first transistor;
a second wiring connected to a gate of the second transistor and disposed adjacent to the first wiring; and
a control circuit operatively coupled to the first and second strings, wherein
when the first string is configured as an operation target during an operation, the control circuit is configured to:
apply a first voltage having a positive voltage value to each of the plurality of word lines;
apply a second voltage having a positive voltage value to the first wiring; and
apply a third voltage having a negative voltage value to the second wiring.

2. The memory device according to claim 1, further comprising:
a first member separating the first wiring from the second wiring, wherein the first string includes a first pillar portion,
the second string includes a second pillar portion, and
the first member is provided between the first pillar portion and the second pillar portion and overlaps with one end of the first pillar portion and one end of the second pillar portion.

3. The memory device according to claim 1, further comprising:
a third string including a plurality of third memory cells, with gates respectively connected to the plurality of word lines, and a third transistor connected to one end of the plurality of third memory cells; and
a third wiring connected to a gate of the third transistor, wherein
the second wiring is provided between the first wiring and the third wiring, and
the control circuit is configured to apply, to the third wiring when the operation is performed, a fourth voltage having a voltage value equal to or less than 0 V during the operation.

4. The memory device according to claim 3, wherein
the voltage value of the fourth voltage is a negative voltage value between the voltage value of the third voltage and V.

5. The memory device according to claim 1, further comprising:
a fourth wiring; and
a fifth wiring disposed adjacent to the fourth wiring, wherein
the first string includes a fourth transistor connected to the other end of the plurality of first memory cells,
the second string includes a fifth transistor connected to the other end of the plurality of second memory cells,
the fourth wiring is connected to a gate of the fourth transistor,
the fifth wiring is connected to a gate of the fifth transistor, and
the control circuit, when performing the operation, is further configured to:
apply a fifth voltage having a positive voltage value to the fourth wiring; and
apply a sixth voltage having a negative voltage value to the fifth wiring.

6. The memory device according to claim 5, wherein
the control circuit is further configured to:
apply the third voltage to the second wiring at a first time; and
apply the sixth voltage to the fifth wiring at a second time different from the first time.

7. The memory device according to claim 5, wherein
the voltage value of the sixth voltage is different from the voltage value of the third voltage.

8. The memory device according to claim 1, further comprising:
a dummy word line, wherein
the first string includes a first dummy cell connected between the first transistor and the one end of the plurality of first memory cells,
the second string includes a second dummy cell connected between the second transistor and the one end of the plurality of second memory cells,
the dummy word line is connected to a gate of the first dummy cell and a gate of the second dummy cell, and
the control circuit is configured to apply a seventh voltage having a positive voltage value lower than the first voltage to the dummy word line when the operation is performed.

9. The memory device according to claim 1, wherein
the operation is a read operation, and
the control circuit is configured to apply a read voltage lower than the first voltage to a selected word line among the plurality of word lines after applying the first voltage to the plurality of word lines.

10. The memory device according to claim 1, wherein
the operation is a write operation, and
the control circuit is configured to apply a program voltage higher than the first voltage to a selected word line among the plurality of word lines after applying the first voltage to the plurality of word lines.

11. A memory device comprising:
a first wiring layer configured as a word line;
a second wiring layer provided above the first wiring layer in a first direction perpendicular to a surface of the first wiring layer and configured as a portion of a first wiring;
a third wiring layer provided between the first wiring layer and the second wiring layer, and configured as another portion of the first wiring;
a fourth wiring layer provided above the first wiring layer in the first direction, disposed adjacent to the second wiring layer in a second direction parallel to the surface of the first wiring layer, and configured as a portion of a second wiring;
a fifth wiring layer provided between the first wiring layer and the fourth wiring layer, and configured as another portion of the second wiring;
a plurality of pillar portions extending in the first direction, penetrating the first to fifth wiring layers, and arranged as an array;
a first member provided between the second wiring layer and the fourth wiring layer and separating the fourth wiring layer from the second wiring layer; and
a second member provided between the third wiring layer and the fifth wiring layer and separating the fifth wiring layer from the third wiring layer, wherein
the second member is shifted from the first member in the second direction.

12. The memory device according to claim 11, wherein
the plurality of pillar portions are aligned in the second direction,
the first member overlaps with a k-th pillar portion among the plurality of pillar portions,
the second member overlaps with a (k+1)th pillar portion among the plurality of pillar portions, and
the k is an integer equal to or greater than 1.

13. The memory device according to claim 12, wherein
each of the plurality of pillar portions includes a first semiconductor pillar, and a second semiconductor pillar provided on the first semiconductor pillar in the first direction,
the first member overlaps with the second semiconductor pillar of the k-th pillar portion, and
the second member overlaps with the first semiconductor pillar of the (k+1)-th pillar portion.

14. The memory device according to claim 13, wherein
the first semiconductor pillar of the k-th pillar portion penetrates the third wiring layer,
the second semiconductor pillar of the k-th pillar portion includes a first portion facing the second wiring layer and a second portion facing the fourth wiring layer,
the first semiconductor pillar of the (k+1)-th pillar portion includes a third portion facing the third wiring layer and a fourth portion facing the fifth wiring layer, and
the second semiconductor pillar of the (k+1)-th pillar portion penetrates the fourth wiring layer.

15. The memory device according to claim 11, further comprising:
a sixth wiring layer provided below the first wiring layer in the first direction and configured as a portion of a third wiring;
a seventh wiring layer provided between the first wiring layer and the sixth wiring layer and configured as another portion of the third wiring;
an eighth wiring layer provided below the first wiring layer in the first direction, disposed adjacent to the sixth wiring layer in the second direction, and configured as a portion of a fourth wiring;
a ninth wiring layer provided between the first wiring layer and the eighth wiring layer and configured as another portion of the fourth wiring;
a third member provided between the sixth wiring layer and the eighth wiring layer and separating the eighth wiring layer from the sixth wiring layer; and
a fourth member provided between the seventh wiring layer and the ninth wiring layer and separating the ninth wiring layer from the seventh wiring layer, wherein
the fourth member is shifted from the third member in the second direction.

16. The memory device according to claim 15, wherein
the third member overlaps with the second member in the first direction, and
the fourth member overlaps with the first member in the first direction.

17. The memory device according to claim 15, wherein
the third member overlaps with the first member in the first direction, and
the fourth member overlaps with the second member in the first direction.

18. The memory device according to claim 11, wherein
each of the first and second members extends and meanders in a third direction that is parallel to a surface of the first wiring layer, and intersects with the second direction,
the plurality of pillar portions are aligned in the second direction,
the first and second members are provided between a k-th pillar portion and a (k+1)-th pillar portion among the plurality of pillar portions,
the first member overlaps with an end of the k-th pillar portion,
the second member overlaps with an end of the (k+1)-th pillar portion,
the k-th pillar portion faces the fourth wiring layer via the first member,
the (k+1)-th pillar portion corresponds to the third wiring layer via the second member, and
the k is an integer equal to or greater than 1.

19. The memory device according to claim 18, wherein
each of the plurality of pillar portions includes a first semiconductor pillar, and a second semiconductor pillar provided on the first semiconductor pillar in the first direction,
the first semiconductor pillar of the k-th pillar portion has a circular planar shape,
the second semiconductor pillar of the k-th pillar portion overlaps with the first member, and the second semiconductor pillar of the k-th pillar portion has a non-circular planar shape in which an arc is chipped off, when viewed from the first direction,
the first semiconductor pillar of the (k+1)-th pillar portion overlaps with the second member, and the first semiconductor pillar of the (k+1)-th pillar portion has a non-circular planar shape in which an arc is chipped off, when viewed from the first direction, and
the second semiconductor pillar of the (k+1)-th pillar portion has a circular planar shape.

20. The memory device according to claim 11, wherein
the first member is continuous with the second member, and
the first member extends toward the second member in a direction oblique to the first direction.
